(19) United States
(12) Patent Application Publication
(10) Pub. No.: US 2025/0089302 A1
(43) Pub. Date: Mar. 13, 2025

(54) SEMICONDUCTOR DEVICE AND METHOD FOR MANUFACTURING SEMICONDUCTOR DEVICE

(71) Applicant: Japan Display Inc., Tokyo (JP)

(72) Inventors: Takaya TAMARU, Tokyo (JP); Masashi TSUBUKU, Tokyo (JP); Hajime WATAKABE, Tokyo (JP); Toshinari SASAKI, Tokyo (JP)

(73) Assignee: Japan Display Inc., Tokyo (JP)

(21) Appl. No.: 18/960,197

(22) Filed: Nov. 26, 2024

Related U.S. Application Data
(63) Continuation of application No. PCT/JP2023/020247, filed on May 31, 2023.

(30) Foreign Application Priority Data
Jun. 7, 2022 (JP) 2022-092534

(51) Int. Cl. H01L 29/786; H01L 29/66

(52) U.S. Cl. CPC H10D 30/6755; H10D 30/0321

(57) ABSTRACT

A semiconductor device includes a metal oxide layer containing aluminum as a main component above an insulating surface, an oxide semiconductor layer on the metal oxide layer; a gate electrode facing the oxide semiconductor layer, and a gate insulating layer between the oxide semiconductor layer and the gate electrode, wherein a water contact angle on an upper surface of the metal oxide layer is 20° or lower.

This application is a Continuation of International Patent Application No. PCT/JP2023/20247, filed on May 31, 2023, which claims the benefit of priority to Japanese Patent Application No. 2022-92534, filed on Jun. 7, 2022, the entire contents of which are incorporated herein by reference.

### FIELD

An embodiment of the present invention relates to a semiconductor device and a method for manufacturing a semiconductor device. In particular, an embodiment of the present invention relates to a semiconductor device in which an oxide semiconductor is used as a channel and a method for manufacturing the semiconductor device.

### BACKGROUND

In recent years, a semiconductor device in which an oxide semiconductor is used for a channel instead of amorphous silicon, low-temperature polysilicon, and single-crystal silicon has been developed (for example, Japanese laid-open patent publication No. 2021-141338, Japanese laid-open patent publication No. 2014-099601, Japanese laid-open patent publication No. 2021-153196, Japanese laid-open patent publication No. 2018-006730, Japanese laid-open patent publication No. 2016-184771, and Japanese laid-open patent publication No. 2021-108405). The semiconductor device in which the oxide semiconductor is used for the channel can be formed with a simple structure and a low-temperature process, similar to a semiconductor device in which amorphous silicon is used as a channel. The semiconductor device in which the oxide semiconductor is used for the channel is known to have higher mobility than the semiconductor device in which amorphous silicon is used for the channel.

It is essential to supply oxygen to an oxide semiconductor layer in the manufacturing process and to reduce the oxygen deficiencies formed in the oxide semiconductor layer in order for the semiconductor device in which the oxide semiconductor is used for the channel to perform a stable operation. For example, a technique of forming an insulating layer covering the oxide semiconductor layer under the condition that the insulating layer contains more oxygen is disclosed as one method of supplying oxygen to the oxide semiconductor layer.

### SUMMARY

A semiconductor device according to an embodiment of the present invention includes a metal oxide layer containing aluminum as a main component above an insulating surface, an oxide semiconductor layer on the metal oxide layer, a gate electrode facing the oxide semiconductor layer, and a gate insulating layer between the oxide semiconductor layer and the gate electrode, wherein a water contact angle on an upper surface of the metal oxide layer is 20° or lower.

A method for manufacturing semiconductor device according to an embodiment of the present invention includes forming a metal oxide layer containing aluminum as a main component on an insulating surface, plasma-treating a surface of the metal oxide layer so that a water contact angle on the insulating surface of the metal oxide layer is 20° or less, forming an oxide semiconductor on the surface of the metal oxide layer that has been plasma-treated, forming a gate insulating layer on the oxide semiconductor layer and forming a gate electrode facing the oxide semiconductor layer on the gate insulating layer.

### BRIEF DESCRIPTION OF DRAWINGS

FIG. 1 is a cross-sectional view showing an outline of a semiconductor device according to an embodiment of the present invention.

FIG. 2 is a plan view showing an outline of a semiconductor device according to an embodiment of the present invention.

FIG. 3 is a sequence diagram showing a method for manufacturing a semiconductor device according to an embodiment of the present invention.

FIG. 4 is a cross-sectional view showing a method for manufacturing a semiconductor device according to an embodiment of the present invention.

FIG. 5 is a cross-sectional view showing a method for manufacturing a semiconductor device according to an embodiment of the present invention.

FIG. 6 is a cross-sectional view showing a method for manufacturing a semiconductor device according to an embodiment of the present invention.

FIG. 7 is a cross-sectional view showing a method for manufacturing a semiconductor device according to an embodiment of the present invention.

FIG. 8 is a cross-sectional view showing a method for manufacturing a semiconductor device according to an embodiment of the present invention.

FIG. 9 is a cross-sectional view showing a method for manufacturing a semiconductor device according to an embodiment of the present invention.

FIG. 10 is a cross-sectional view showing a method for manufacturing a semiconductor device according to an embodiment of the present invention.

FIG. 11 is a cross-sectional view showing a method for manufacturing a semiconductor device according to an embodiment of the present invention.

FIG. 12 is a cross-sectional view showing a method for manufacturing a semiconductor device according to an embodiment of the present invention.

FIG. 13 is a cross-sectional view showing a method for manufacturing a semiconductor device according to an embodiment of the present invention.

FIG. 14 is a sequence diagram showing a method for manufacturing a semiconductor device according to a modification of an embodiment of the present invention.

FIG. 15 is a cross-sectional view showing a method for manufacturing a semiconductor device according to a modification of an embodiment of the present invention.

FIG. 16 is a cross-sectional view showing a method for manufacturing a semiconductor device according to a modification of an embodiment of the present invention.

FIG. 17 is a cross-sectional view showing an outline of a semiconductor device according to a modification of an embodiment of the present invention.

FIG. 18 is a sequence diagram showing a method for manufacturing a semiconductor device according to a modification of an embodiment of the present invention.

FIG. 19 is a cross-sectional view showing an outline of a semiconductor device according to a modification of an embodiment of the present invention.

FIG. 20 is a plan view showing an outline of a semiconductor device according to a modification of an embodiment of the present invention.

FIG. 21 is a sequence diagram showing a method for manufacturing a semiconductor device according to a modification of an embodiment of the present invention.

FIG. 22 is a cross-sectional view showing a method for manufacturing a semiconductor device according to a modification of an embodiment of the present invention.

FIG. 23 is a cross-sectional view showing a method for manufacturing a semiconductor device according to a modification of an embodiment of the present invention.

FIG. 24 is a sequence diagram showing a method for manufacturing a semiconductor device according to an embodiment of the present invention.

FIG. 25 is a cross-sectional view showing a method for manufacturing a semiconductor device according to an embodiment of the present invention.

FIG. 26 is a cross-sectional view showing a method for manufacturing a semiconductor device according to an embodiment of the present invention.

FIG. 27 is a cross-sectional view showing a method for manufacturing a semiconductor device according to an embodiment of the present invention.

FIG. 28 is a cross-sectional view showing a method for manufacturing a semiconductor device according to an embodiment of the present invention.

FIG. 29 is a cross-sectional view showing a method for manufacturing a semiconductor device according to an embodiment of the present invention.

FIG. 30 is a cross-sectional view showing a method for manufacturing a semiconductor device according to an embodiment of the present invention.

FIG. 31 is a cross-sectional view showing a method for manufacturing a semiconductor device according to an embodiment of the present invention.

FIG. 32 is a cross-sectional view showing a method for manufacturing a semiconductor device according to an embodiment of the present invention.

FIG. 33 is a cross-sectional view showing a method for manufacturing a semiconductor device according to an embodiment of the present invention.

FIG. 34 is a cross-sectional view showing a method for manufacturing a semiconductor device according to an embodiment of the present invention.

FIG. 35 is a cross-sectional view showing a method for manufacturing a semiconductor device according to an embodiment of the present invention.

FIG. 36 is a plan view showing an outline of a semiconductor device according to an embodiment of the present invention.

FIG. 37 is a block diagram showing a circuit configuration of a display device according to an embodiment of the present invention.

FIG. 38 is a circuit diagram showing a pixel circuit of a display device according to an embodiment of the present invention.

FIG. 39 is a cross-sectional view showing an outline of a display device according to an embodiment of the present invention.

FIG. 40 is a plan view of a pixel electrode and a common electrode of a display device according to an embodiment of the present invention.

FIG. 41 is a circuit diagram showing a pixel circuit of a display device according to an embodiment of the present invention.

FIG. 42 is a cross-sectional view showing an outline of a display device according to an embodiment of the present invention.

FIG. 43 is a diagram showing the results of XPS spectrometry by a plasma treatment on a surface of a metal oxide layer.

FIG. 44 is a diagram showing reliability test results of a semiconductor device to which Condition 1 is applied.

FIG. 45 is a diagram showing reliability test results of a semiconductor device to which Condition 2 is applied.

FIG. 46 is a diagram showing reliability test results of a semiconductor device to which Condition 3 is applied.

FIG. 47 is a diagram showing reliability test results of a semiconductor device to which Condition 4 is applied.

FIG. 48 is a diagram showing reliability test results of a semiconductor device to which Condition 5 is applied.

### DESCRIPTION OF EMBODIMENTS

An insulating layer formed with more oxygen-containing conditions contains more defects. As a result, abnormal characteristics of the semiconductor device or a variation in characteristics in a reliability test occur, which are considered to be caused by electrons becoming trapped in the defect. On the other hand, if an insulating layer with fewer defects is used, oxygen in the insulating layer cannot be increased. Therefore, sufficient oxygen cannot be supplied from the insulating layer to the oxide semiconductor layer. As described above, there is a demand for realizing a structure capable of repairing oxygen deficiencies formed in the oxide semiconductor layer while reducing defects in the insulating layer that cause the variation in characteristics of the semiconductor device.

Further, a semiconductor device with high mobility can be obtained by relatively increasing a ratio of indium contained in the oxide semiconductor layer. However, if the ratio of indium contained in the oxide semiconductor layer is high, oxygen deficiencies are likely to be formed in the oxide semiconductor layer. Therefore, in order to realize high mobility while maintaining high reliability, it is necessary to devise a configuration of the insulating layer around the oxide semiconductor layer.

An object of an embodiment of the present invention is to realize a semiconductor device with high reliability and mobility.

Embodiments of the present invention will be described below with reference to the drawings. The following disclosure is merely an example. A configuration that can be easily conceived by a person skilled in the art by appropriately changing the configuration of the embodiment while maintaining the gist of the invention is naturally included in the scope of the present invention. For the sake of clarity of description, the drawings may be schematically represented with respect to widths, thicknesses, shapes, and the like of the respective portions in comparison with actual embodiments. However, the shape shown is merely an example and does not limit the interpretation of the present invention. In this specification and each of the drawings, the same symbols are assigned to the same components as those described previously with reference to the preceding drawings, and a detailed description thereof may be omitted as appropriate.

“Semiconductor device” refers to all devices that can function by utilizing semiconductor characteristics. Transistors and semiconductor circuits are one form of a semiconductor device. For example, a semiconductor device may be used in an integrated circuit (IC) such as a micro-processing unit (MPU) or a memory circuit in addition to a transistor used in a display device.

“Display device” refers to a structure configured to display an image using electro-optic layers. For example, the term display device may refer to a display panel including the electro-optic layer, or it may refer to a structure in which other optical members (e.g., polarizing member, backlight, touch panel, etc.) are attached to a display cell. The “electro-optic layer” can include a liquid crystal layer, an electroluminescence (EL) layer, an electrochromic (EC) layer, and an electrophoretic layer, as long as there is no technical contradiction. Therefore, although the embodiments described later will be described by exemplifying the liquid crystal display device including a liquid crystal layer and an organic EL display device including an organic EL layer as the display device, the structure in the present embodiment can be applied to a display device including the other electro-optic layers described above.

In the embodiments of the present invention, a direction from a substrate to an oxide semiconductor layer is referred to as “on” or “above”. Reversely, a direction from the oxide semiconductor layer to the substrate is referred to as “under” or “below”. As described above, for convenience of explanation, although the phrase “above (on)” or “below (under)” is used for explanation, for example, a vertical relationship between the substrate and the oxide semiconductor layer may be arranged in a different direction from that shown in the drawing. In the following description, for example, the expression “the oxide semiconductor layer on the substrate” merely describes the vertical relationship between the substrate and the oxide semiconductor layer as described above, and other members may be arranged between the substrate and the oxide semiconductor layer. Above or below means a stacking order in a structure in which multiple layers are stacked, and when it is expressed as a pixel electrode above a transistor, it may be a positional relationship where the transistor and the pixel electrode do not overlap each other in a plan view. On the other hand, when it is expressed as a pixel electrode vertically above a transistor, it means a positional relationship where the transistor and the pixel electrode overlap each other in a plan view.

The expressions “a includes A, B, or C”, “a includes any of A, B, and C”, and “α includes one selected from a group consisting of A, B, and C” do not exclude the case where α includes multiple combinations of A to C unless otherwise specified. Furthermore, these expressions do not exclude the case where α includes other elements.

In addition, the following embodiments may be combined with each other as long as there is no technical contradiction.

### First Embodiment

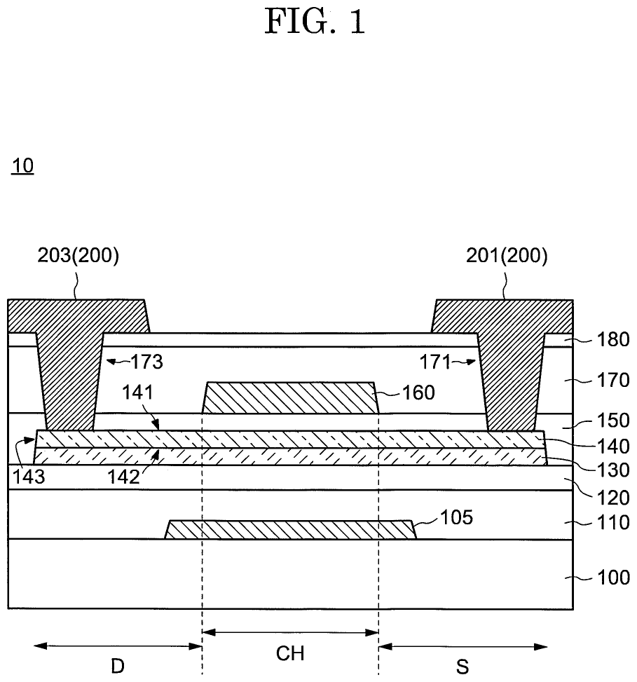

A semiconductor device 10 according to an embodiment of the present invention will be described with reference to FIG. 1 to FIG. 13.

### [Configuration of Semiconductor Device 10]

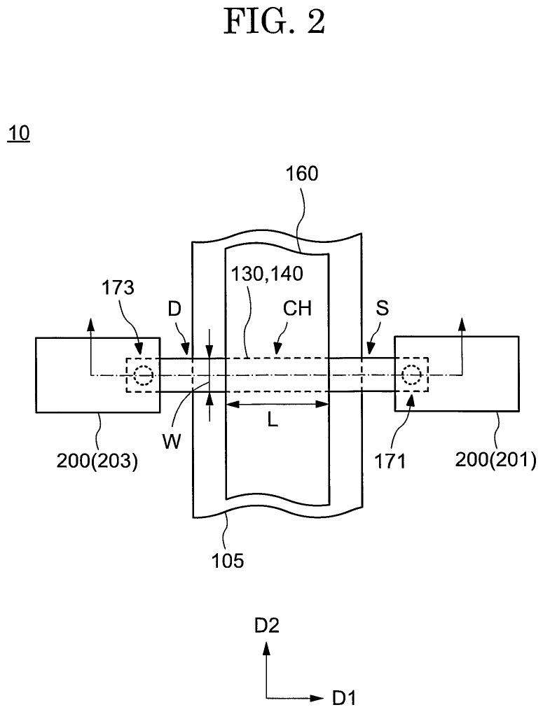

A configuration of the semiconductor device 10 according to an embodiment of the present invention will be described with reference to FIG. 1 and FIG. 2. FIG. 1 is a cross-sectional view showing an outline of a semiconductor device according to an embodiment of the present invention. FIG. 2 is a plan view showing an outline of a semiconductor device according to an embodiment of the present invention.

As shown in FIG. 1, the semiconductor device 10 is arranged above a substrate 100. The semiconductor device 10 includes a gate electrode 105, gate insulating layers 110 and 120, a metal oxide layer 130, an oxide semiconductor layer 140, a gate insulating layer 150, a gate electrode 160, insulating layers 170 and 180, a source electrode 201, and a drain electrode 203. If the source electrode 201 and the drain electrode 203 are not specifically distinguished from each other, they may be referred to as a source-drain electrode 200.

The gate electrode 105 is arranged on the substrate 100. The gate insulating layer 110 and the gate insulating layer 120 are arranged on the substrate 100 and the gate electrode 105. The metal oxide layer 130 is arranged on the gate insulating layer 120. The metal oxide layer 130 is in contact with the gate insulating layer 120. The oxide semiconductor layer 140 is arranged on the metal oxide layer 130. The oxide semiconductor layer 140 is in contact with the metal oxide layer 130. A surface of the main surface of the oxide semiconductor layer 140 in contact with the metal oxide layer 130 is referred to as a bottom surface 142. An end portion of the metal oxide layer 130 and an end portion of the oxide semiconductor layer 140 substantially coincide.

In the present embodiment, a semiconductor layer or an oxide semiconductor layer is not arranged between the metal oxide layer 130 and the substrate 100.

Although a configuration in which the metal oxide layer 130 is in contact with the gate insulating layer 120 and the oxide semiconductor layer 140 is in contact with the metal oxide layer 130 is exemplified in the present embodiment, the configuration is not limited to this configuration. Other layers may be arranged between the gate insulating layer 120 and the metal oxide layer 130. Other layers may be arranged between the metal oxide layer 130 and the oxide semiconductor layer 140.

In FIG. 1, the sidewalls of the metal oxide layer 130 and the sidewalls of the oxide semiconductor layer 140 are arranged in a straight line, but the configuration is not limited to this. An angle of the sidewalls of the metal oxide layer 130 with respect to the main surface of the substrate 100 may be different from an angle of the sidewalls of the oxide semiconductor layer 140. The cross-sectional shapes of the sidewalls of at least one of the metal oxide layer 130 and the oxide semiconductor layer 140 may be curved.

The gate electrode 160 faces the oxide semiconductor layer 140. The gate insulating layer 150 is arranged between the oxide semiconductor layer 140 and the gate electrode 160. The gate insulating layer 150 is in contact with the oxide semiconductor layer 140. Within the main surface of the oxide semiconductor layer 140, a surface in contact with the gate insulating layer 150 is referred to as an upper surface 141. A surface between the upper surface 141 and the lower surface 142 is referred to as a side surface 143. The insulating layers 170 and 180 are arranged above the gate insulating layer 150 and the gate electrode 160. Openings 171 and 173 that reach the oxide semiconductor layer 140 are arranged in the insulating layers 170 and 180. The source electrode 201 is arranged inside the opening 171. The source electrode 201 is in contact with the oxide semiconductor layer 140 at a bottom of the opening 171. The drain electrode 203 is arranged inside the opening 173. The drain electrode 203 is in contact with the oxide semiconductor layer 140 at a bottom of the opening 173.

The gate electrode 105 has a function as a bottom-gate of the semiconductor device 10 and a function as a light-shielding film for the oxide semiconductor layer 140. The gate insulating layer 110 has a function as a barrier film for shielding impurities that diffuse from the substrate 100 toward the oxide semiconductor layer 140. The gate insulating layers 110 and 120 have a function as a gate insulating layer for the bottom-gate. The metal oxide layer 130 is a layer containing a metal oxide containing aluminum as a main component, and has a function as a gas barrier film for shielding a gas such as oxygen or hydrogen.

The oxide semiconductor layer 140 is divided into a source region S, a drain region D, and a channel region CH. The channel region CH is a region of the oxide semiconductor layer 140 vertically below the gate electrode 160. The source region S is a region of the oxide semiconductor layer 140 that does not overlap the gate electrode 160 and is closer to the source electrode 201 than the channel region CH. The drain region D is a region of the oxide semiconductor layer 140 that does not overlap the gate electrode 160 and is closer to the drain electrode 203 than the channel region CH. The oxide semiconductor layer 140 in the channel region CH has physical properties as a semiconductor. The oxide semiconductor layer 140 in the source region S and the drain region D has physical properties as a conductor.

The gate electrode 160 has a function as a top-gate of the semiconductor device 10 and a light-shielding film for the oxide semiconductor layer 140. The gate insulating layer 150 has a function as a gate insulating layer for the top-gate, and has a function of releasing oxygen by a heat treatment in a manufacturing process. The insulating layers 170 and 180 insulate the gate electrode 160 and the source-drain electrode 200 and have a function of reducing parasitic capacitance therebetween. Operations of the semiconductor device 10 are controlled mainly by a voltage supplied to the gate electrode 160. An auxiliary voltage is supplied to the gate electrode 105. However, in the case of using the gate electrode 105 simply as a light-shielding film, a specific voltage is not supplied to the gate electrode 105, and the gate electrode 105 may be in a floating state. That is, the gate electrode 105 may simply be referred to as a “light-shielding film.”

Although a configuration in which a dual-gate transistor in which a gate electrode is arranged both above and below the oxide semiconductor layer is used as the semiconductor device 10 is exemplified in the present embodiment, the configuration is not limited to this configuration. For example, a bottom-gate transistor in which a gate electrode is arranged only below the oxide semiconductor layer or a top-gate transistor in which a gate electrode is arranged only above the oxide semiconductor layer may be used as the semiconductor device 10. The above configuration is merely an embodiment, and the present invention is not limited to the above configuration.

As shown in FIG. 2, a planar pattern of the metal oxide layer 130 is substantially the same as a planar pattern of the oxide semiconductor layer 140 in a plan view. Referring to FIG. 1 and FIG. 2, the bottom surface 142 of the oxide semiconductor layer 140 is covered with the metal oxide layer 130. In particular, in the present embodiment, all of the bottom surface 142 of the oxide semiconductor layer 140 is covered with the metal oxide layer 130. In a first direction D1, a width of the gate electrode 105 is greater than a width of the gate electrode 160. The first direction D1 is a direction connecting the source electrode 201 and the drain electrode 203, and is a direction indicating a channel length L of the semiconductor device 10. Specifically, a length of the first direction D1 in a region (channel region CH) where the oxide semiconductor layer 140 and the gate electrode 160 overlap is the channel length L, and a width of the channel region CH in a second direction D2 is a channel width W.

Although the configuration in which all of the bottom surface 142 of the oxide semiconductor layer 140 is covered with the metal oxide layer 130 has been exemplified in the present embodiment, the configuration is not limited to this configuration. For example, part of the bottom surface 142 of the oxide semiconductor layer 140 may not be in contact with the metal oxide layer 130. For example, all of the bottom surface 142 of the oxide semiconductor layer 140 in the channel region CH may be covered with the metal oxide layer 130, and all or part of the bottom surface 142 of the oxide semiconductor layer 140 in the source region S and the drain region D may not be covered with the metal oxide layer 130. That is, all or part of the bottom surface 142 of the oxide semiconductor layer 140 in the source region S and the drain region D may not be in contact with the metal oxide layer 130. However, in the above configuration, part of the bottom surface 142 of the oxide semiconductor layer 140 in the channel region CH may not be covered with the metal oxide layer 130, and another part of the bottom surface 142 may be in contact with the metal oxide layer 130.

Although a configuration in which the gate insulating layer 150 is formed on the entire surface and the openings 171 and 173 are arranged in the gate insulating layer 150 has been exemplified, the configuration is not limited to this configuration. The gate insulating layer 150 may be patterned. For example, the gate insulating layer 150 may be patterned to expose the oxide semiconductor layer 140 in the source region S and the drain region D. That is, the gate insulating layer 150 in the source region S and the drain region D may be removed, and the oxide semiconductor layer 140 and the insulating layer 170 may be in contact with each other in these regions.

Although a configuration in which the source-drain electrode 200 does not overlap the gate electrode 105 and the gate electrode 160 in a plan view is exemplified in FIG. 2, the configuration is not limited to this configuration. For example, the source-drain electrode 200 may overlap at least one of the gate electrode 105 and the gate electrode 160 in a plan view. The above configuration is merely an embodiment, and the present invention is not limited to the above configuration.

### [Material of Each Member of Semiconductor Device 10]

A rigid substrate having light transmittance, such as a glass substrate, a quartz substrate, and a sapphire substrate is used as the substrate 100. In the case where the substrate 100 needs to be flexible, a substrate containing a resin such as a polyimide substrate, an acryl substrate, a siloxane substrate, or a fluororesin substrate is used as the substrate 100. In the case where a substrate containing a resin is used as the substrate 100, an impurity may be introduced into the resin in order to improve the heat resistance of the substrate 100. In particular, in the case where the semiconductor device 10 is a top-emission display, the substrate 100 does not need to be transparent, so an impurity that reduces the transparency of the substrate 100 may be used. In the case where the semiconductor device 10 is used as an integrated circuit which is not a display device, a semiconductor substrate such as a silicon substrate, a silicon carbide substrate, a compound semiconductor substrate, or a substrate without light transmittance such as a conductive substrate such as a stainless substrate is used as the substrate 100.

Common metal materials are used as the gate electrode 105, the gate electrode 160, and the source-drain electrode 200. For example, aluminum (Al), titanium (Ti), chromium (Cr), cobalt (Co), nickel (Ni), molybdenum (Mo), hafnium (Hf), tantalum (Ta), tungsten (W), bismuth (Bi), silver (Ag), copper (Cu), and an alloy thereof or compound thereof are used as these members. The above-described materials may be used in a single layer or stacked layer as the gate electrode 105, the gate electrode 160, and the source-drain electrode 200.

Common insulating materials are used as the gate insulating layers 110 and 120 and the insulating layers 170 and 180. For example, inorganic insulating layers such as silicon oxide (SiOx), silicon oxynitride (SiOxNy), silicon nitride (SiNx), silicon nitride oxide (SiNxOy), aluminum oxide (AlOx), aluminum oxynitride (AlOxNy), aluminum nitride oxide (AlNxOy), and aluminum nitride (AlNx) are used as these insulating layers.

Among the above-described insulating layers, the insulating layer containing oxygen is used as the gate insulating layer 150. For example, an inorganic insulating layer such as silicon oxide (SiOx), silicon oxynitride (SiOxNy), aluminum oxide (AlOx), or aluminum oxynitride (AlOxNy) is used as the gate insulating layer 150.

An insulating layer having a function of releasing oxygen by the heat treatment is used as the gate insulating layer 120. For example, the temperature of the heat treatment at which the gate insulating layer 120 releases oxygen is 600° C. or lower, 500° C. or lower, 450° C. or lower, or 400° C. or lower. That is, for example, in the case where a glass substrate is used as the substrate 100, the gate insulating layer 120 releases oxygen at the heat treatment temperature performed in the manufacturing process of the semiconductor device 10.

An insulating layer with few defects is used as the gate insulating layer 150. For example, in the case where a composition ratio of oxygen in the gate insulating layer 150 is compared with a composition ratio of oxygen in an insulating layer having a composition similar to that of the gate insulating layer 150 (hereinafter referred to as “other insulating layer”), the composition ratio of oxygen in the gate insulating layer 150 is closer to the stoichiometric ratio with respect to the insulating layer than the composition ratio of oxygen in the other insulating layer. Specifically, in the case where silicon oxide (SiOx) is used for each of the gate insulating layer 150 and the insulating layer 180, the composition ratio of oxygen in the silicon oxide used as the gate insulating layer 150 is close to the stoichiometric ratio of silicon oxide as compared with the composition ratio of oxygen in the silicon oxide used as the insulating layer 180. For example, a layer in which no defects are observed when evaluated by an electron-spin resonance (ESR) method may be used as the gate insulating layer 150.

SiOxNy and AlOxNy are a silicon compound and an aluminum compound containing a lower proportion (x>y) of nitrogen (N) than oxygen (O). SiNxOy and AlNxOy are a silicon compound and an aluminum compound containing a lower proportion (x>y) of oxygen than nitrogen.

A metal oxide containing aluminum as a main component is used as the metal oxide layer 130. For example, an inorganic insulating layer such as aluminum oxide (AlOx), aluminum oxynitride (AlOxNy), aluminum nitride oxide (AlNxOy), or aluminum nitride (AlNx) is used as the metal oxide layer 130. The “metal oxide layer containing aluminum as a main component” means that the proportion of aluminum contained in the metal oxide layer 130 is 1% or more of the entire metal oxide layer 130. The proportion of aluminum contained in the metal oxide layer 130 may be 5% or more and 70% or less, 10% or more and 60% or less, or 30% or more and 50% or less of the entire metal oxide layer 130. The ratio may be a mass ratio or a weight ratio.

A metal oxide having semiconductor properties can be used as the oxide semiconductor layer 140. For example, an oxide semiconductor containing two or more metals including indium (In) is used as the oxide semiconductor layer 140. The proportion of indium to the entire oxide semiconductor layer 140 is 50% or more. Gallium (Ga), zinc (Zn), aluminum (Al), hafnium (Hf), yttrium (Y), zirconia (Zr), and lanthanoids are used as the oxide semiconductor layer 140 in addition to indium. Elements other than those described above may be used as the oxide semiconductor layer 140.

In the present embodiment, the oxide semiconductor layer 140 has a polycrystalline structure. That is, the oxide semiconductor layer 140 of the present embodiment is composed of an oxide semiconductor formed using a poly-OS (Poly-crystalline Oxide Semiconductor) technique. The poly-OS technique refers to a technique of forming an oxide semiconductor layer having a polycrystalline structure. In the present embodiment, as will be described later, the oxide semiconductor layer 140 is crystallized by performing the heat treatment on the oxide semiconductor layer 140 formed by a sputtering method.

### [Problems Newly Recognized in the Process Leading to the Present Invention]

Since the proportion of indium in the oxide semiconductor layer 140 is 50% or more, the semiconductor device 10 with high mobility is realized. On the other hand, in such an oxide semiconductor layer, oxygen contained in the oxide semiconductor layer 140 is easily reduced, so that oxygen deficiencies are easily formed in the oxide semiconductor layer 140.

In the semiconductor device 10, hydrogen is released from a layer (for example, the gate insulating layers 110 and 120) arranged closer to the substrate 100 than the oxide semiconductor layer 140 in the heat treatment step of the manufacturing process. When the hydrogen reaches the oxide semiconductor layer 140, an oxygen deficiency occurs in the oxide semiconductor layer 140. The occurrence of the oxygen deficiency is more significant as a pattern size of the oxide semiconductor layer 140 becomes larger. In order to prevent the occurrence of such oxygen deficiencies, it is required to prevent hydrogen from reaching the bottom surface 142 of the oxide semiconductor layer 140. The above is the first problem.

Apart from the above-mentioned problems, there is the following second problem. The upper surface 141 of the oxide semiconductor layer 140 is affected by a process after the oxide semiconductor layer 140 is formed (for example, a patterning process or an etching process). On the other hand, the bottom surface 142 of the oxide semiconductor layer 140 (the surface of the oxide semiconductor layer 140 facing the substrate 100) is not affected as described above.

Therefore, the number of oxygen deficiencies formed near the upper surface 141 of the oxide semiconductor layer 140 is greater than the number of oxygen deficiencies formed near the bottom surface 142 of the oxide semiconductor layer 140. That is, the oxygen deficiencies in the oxide semiconductor layer 140 are not uniformly present in a thickness direction of the oxide semiconductor layer 140, but are non-uniformly distributed in the thickness direction of the oxide semiconductor layer 140. Specifically, the oxygen deficiencies in the oxide semiconductor layer 140 are fewer on the bottom surface 142 side of the oxide semiconductor layer 140 and are more numerous on the upper surface 141 side of the oxide semiconductor layer 140.

In the case where an oxygen supply process is uniformly performed on the oxide semiconductor layer 140 having the oxygen deficiency distribution as described above, when oxygen is supplied in an amount required to repair the oxygen deficiencies formed on the upper surface 141 side of the oxide semiconductor layer 140, oxygen is excessively supplied to the bottom surface 142 side of the oxide semiconductor layer 140. As a result, a defect level different from the oxygen deficiency is formed on the bottom surface 142 side by the excess oxygen. As a result, a phenomenon such as characteristic fluctuations in the reliability test or a decrease in field-effect mobility occurs. Therefore, in order to suppress such a phenomenon, oxygen needs to be supplied to the upper surface 141 side of the oxide semiconductor layer 140 while suppressing an oxygen supply to the bottom surface 142 side of the oxide semiconductor layer 140.

The above-described problem is a newly recognized problem in the process leading to the present invention, and is not a problem that has been conventionally recognized. In the conventional configuration and manufacturing method, there is a trade-off relationship between the initial characteristics and the reliability test, in which the characteristic fluctuations due to the reliability test occur even when the initial characteristics of the semiconductor device are improved by the oxygen supply process to the oxide semiconductor layer. However, with the configuration according to the present embodiment, the above-described problem can be solved, and good initial characteristics and high-reliability of the semiconductor device 10 can be obtained.

In addition, a surface where the oxide semiconductor layer 140 is deposited is a region adjacent to a back channel of the transistor. That is, a region at an interface between the metal oxide layer 130 and the oxide semiconductor layer 140 affects the electrical characteristics of the transistor. Therefore, it is preferable that the surface of the metal oxide layer 130 on which the oxide semiconductor layer 140 is deposited has fewer oxygen deficiencies, hydrogen, or the like that adversely affects the electrical characteristics of the transistor.

However, in the metal oxide layer immediately after being deposited by the sputtering method, surface irregularities are present, or hydrogen is easily bonded due to the influence of the surface energy. Therefore, when the oxide semiconductor layer is deposited on the metal oxide layer immediately after the deposition, hydrogen remains at the interface between the metal oxide layer and oxide semiconductor layer. In addition, when the oxide semiconductor layer is deposited, oxygen deficiencies are likely to occur. As described above, it is difficult to remove oxygen deficiencies and hydrogen present at the interface by subsequent annealing. When oxygen deficiencies and hydrogen present in the interface remain, the interface state density increases. In addition, when electrons are trapped in the interface state, for example, the transistor deteriorates due to the reliability test, which causes the reliability of the semiconductor device to deteriorate. As described above, there is room for further improvement in order to improve the reliability of the semiconductor device.

In an embodiment of the present invention, the upper surface of the metal oxide layer 130 is modified at the interface between the metal oxide layer 130 and the oxide semiconductor layer 140. Although details will be described later, the oxide semiconductor layer 140 is deposited on the modified upper surface of the metal oxide layer 130. The water contact angle on the upper surface of the metal oxide layer 130 is 20° or less, preferably 15° or less, and more preferably 10° or less.

With such a configuration, hydrogen or oxygen deficiencies of the oxide semiconductor layer 140 can be reduced at the interface between the metal oxide layer 130 and the oxide semiconductor layer 140. In particular, even when the oxide semiconductor layer 140 having a relatively high proportion of indium is used, it is possible to suppress the formation of oxygen deficiencies at the interface. Therefore, the crystallinity of the oxide semiconductor layer 140 arranged on the metal oxide layer 130 is improved, and a polycrystal with reduced defects can be formed. As a result, the field-effect mobility of the semiconductor device 10 can be further improved. Specifically, the field-effect mobility of the semiconductor device 10 can be 40 cm²/V·s or more. In addition, the reliability of the semiconductor device is improved by suppressing degradation of the transistor due to the reliability test.

In this case, the reliability test means, for example, an NGBT (Negative Gate Bias-Temperature) stress test where a negative voltage is applied to the gate, or a PGBT (Positive Gate Bias-Temperature) stress test where a positive voltage is applied to the gate. In addition, BT stress tests such as NGBT and PGBT are a kind of accelerated tests, and it is possible to evaluate, in a short time, a characteristic change (aging) of a transistor caused by long-term use. In particular, the amount of variation in a threshold voltage of the transistor before and after the BT stress test is a critical indicator for examining reliability. It can be said that the smaller the amount of variation in the threshold voltage before and after the BT stress test, the more reliable the transistor is.

### [Method for Manufacturing Semiconductor Device 10]

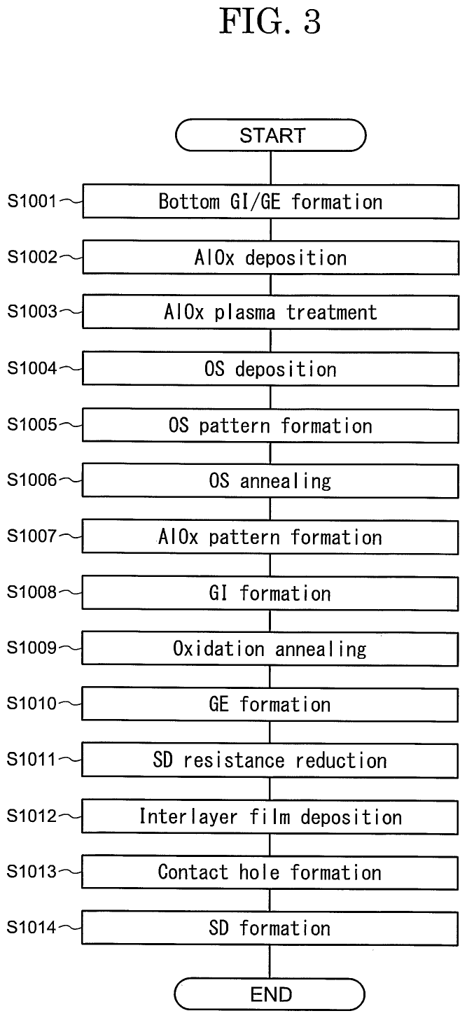

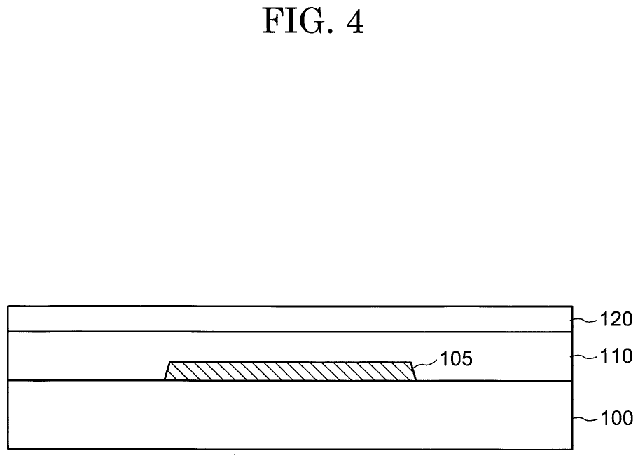

A method for manufacturing a semiconductor device according to an embodiment of the present invention will be described with reference to FIG. 3 to FIG. 13. FIG. 3 is a sequence diagram showing a method for manufacturing a semiconductor device according to an embodiment of the present invention. FIG. 4 to FIG. 13 are cross-sectional views showing a method for manufacturing a semiconductor device according to an embodiment of the present invention. In the following description of the manufacturing method, a method for manufacturing the semiconductor device 10 in which aluminum oxide is used as the metal oxide layer 130 will be described.

As shown in FIG. 3 and FIG. 4, the gate electrode 105 is formed as a bottom gate on the substrate 100, and the gate insulating layers 110 and 120 are formed on the gate electrode 105 (“Bottom GI/GE formation” in step S1001 of FIG. 3). For example, silicon nitride is formed as the gate insulating layer 110. For example, silicon oxide is formed as the gate insulating layer 120. The gate insulating layers 110 and 120 are formed by a CVD (Chemical Vapor Deposition) method.

The use of silicon nitride as the gate insulating layer 110 allows the gate insulating layer 110 to block impurities that diffuse, for example, from the substrate 100 toward the oxide semiconductor layer 140. The silicon oxide used as the gate insulating layer 120 is silicon oxide having a physical property of releasing oxygen by the heat treatment.

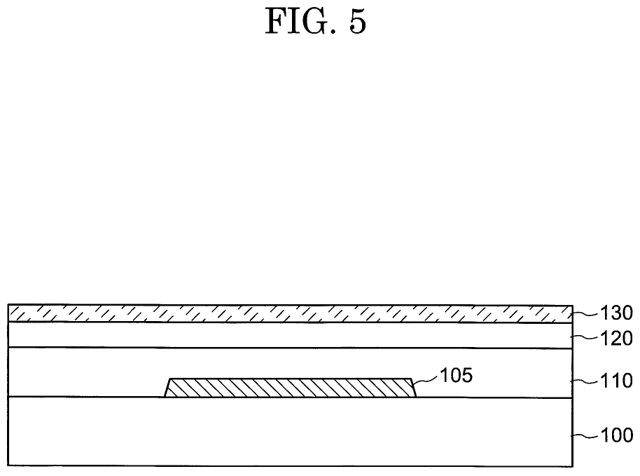

As shown in FIG. 3 and FIG. 5, the metal oxide layer 130 is formed on the gate insulating layer 120 “AlOx deposition” in step S1002 of FIG. 3). The metal oxide layer 130 is deposited by a sputtering method or an atomic layer deposition method (ALD).

For example, a thickness of the metal oxide layer 130 at the time of deposition is 2 nm or more and 51 nm or less, 2 nm or more and 31 nm or less, 2 nm or more and 21 nm or less, or 2 nm or more and 11 nm or less. In the present embodiment, aluminum oxide is used as the metal oxide layer 130. Aluminum oxide has a high barrier property against gases such as oxygen or hydrogen. In other words, the barrier property refers to a function of suppressing gasses such as oxygen or hydrogen from permeating through aluminum oxide. That is, it means that, even if a gas such as oxygen or hydrogen is present, the gas is not transferred from the layer arranged below the aluminum oxide layer to the layer arranged above the aluminum oxide layer. Alternatively, it means that, even if a gas such as oxygen or hydrogen is present, the gas is not transferred from the layer arranged above the aluminum oxide layer to the layer arranged below the aluminum oxide layer. The metal oxide layer 130 is deposited by sputtering. In the present embodiment, the aluminum oxide used as the metal oxide layer 130 blocks hydrogen and oxygen released from the gate insulating layer 120 and suppresses the released hydrogen and oxygen from reaching the oxide semiconductor layer 140.

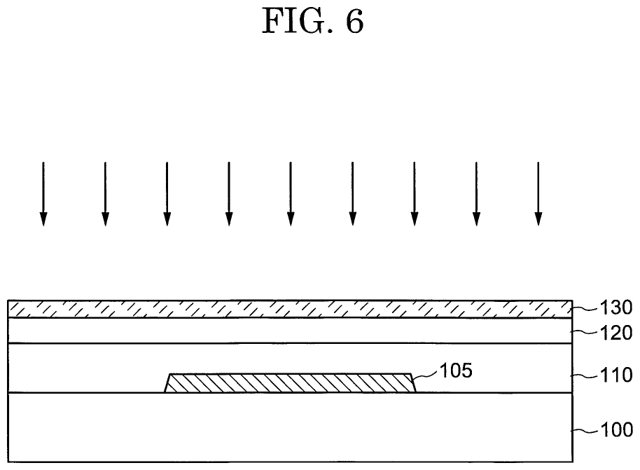

As shown in FIG. 3 and FIG. 6, a plasma treatment is performed on the metal oxide layer 130 (“AlOx plasma treatment” in step S1003 of FIG. 3).

In the present specification and the like, the plasma treatment refers to a treatment in which a substrate to be treated is exposed to plasma by generating plasma in a space where the substrate to be treated is installed. For example, the plasma treatment is performed by reverse sputtering using a sputtering device or etching using an inductively coupled plasma (ICP) device.

The gas used for generating the plasma is preferably a gas that does not affect the physical properties of the oxide semiconductor layer 140 deposited on the aluminum oxide layer. For example, a rare gas such as helium (He), neon (Ne), argon (Ar), krypton (Kr), or xenon (Xe) is used as the gas used for the plasma treatment. The following gases may be used as long as they do not affect the physical properties of the oxide semiconductor layer 140. In the case where the plasma treatment is performed by reverse sputtering, an oxygen gas may be used, or a mixed gas of an oxygen gas and an inert gas may be used. Alternatively, in the case where the plasma treatment is performed by etching, a halogen-based gas such as a chlorine-based gas or a fluorine-based gas may be used. In the present embodiment, the case where an argon gas is used for the plasma treatment will be described.

Reverse sputtering is a process of modifying a surface by forming a plasma in the vicinity of a substrate by applying a voltage using an RF power source in an argon atmosphere without applying a voltage to the target side, thereby causing ions to collide with the surface of the substrate. For example, in the case where the plasma treatment is performed by reverse sputtering, the plasma is generated by introducing argon gas into a chamber before depositing the oxide semiconductor layer 140 by sputtering.

As a specific condition of reverse sputtering, under a suitable upper/lower RF power source feed and in a vacuum environment, the upper/lower electrode power side output of 25 W to 270 W, the temperature of 0° C. to 100° C., without excessively lowering the vacuum in the processing chamber, and sufficient argon gas flow rate to generate plasma well, it is possible to suitably treat the surface of the aluminum oxide layer, and it may be carried out at a processing time sufficient to not cause excessive film reduction. As a specific example, the upper RF power source is 400 kHz, the output is 25 W, the lower RF power source is 13.56 MHZ, the output 25 is W, the argon gas flow rate is 5 sccm, the processing time is 143 seconds, and at room temperature, thereby obtaining about a 1 nm amount of scraping from the surface of the aluminum oxide layer.

Etching with the inductively coupled plasma is a process of modifying the surface of a substrate by ions and radicals present in the plasma.

Specific conditions for etching by the inductively coupled plasma include an ICP power 25 W to 100 W, an RF bias power of 25 W to 100 W, a temperature of 0° C. to 100° C., an argon gas flow rate sufficient to satisfactorily generate a plasma without excessively lowering the vacuum in the processing chamber, and a processing time of 40 seconds (when RF bias power (Source/Bias) 100 W/100 W) to 1100 seconds (when RF bias power (Source/Bias) is 25 W/25 W). As a specific example, the conditions are ICP power 50 W (power per unit-electrode area=0.81 W/cm²), the pressure 4 Pa, the argon gas flow rate 50 sccm, RF bias power (Source/Bias) 50 W/50 W, the temperature 65° C., and the processing time 400 seconds.

The surface of the metal oxide layer 130 is modified by performing a plasma treatment on the metal oxide layer 130. In this case, the modification of the surface means that the chemical composition of the surface of the metal oxide layer 130 changes or the surface roughness of the metal oxide layer 130 decreases.

The magnitude of the water contact angle of the surface can confirm the state of the surface-modified metal oxide layer 130. By performing the plasma treatment on the surface of the metal oxide layer 130, the water contact angle of the metal oxide layer 130 is lowered. The water contact angle on the surface of the metal oxide layer 130 after the plasma treatment is 20° or less, preferably 15° or less, and more preferably 10° or less. In the present specification and the like, a value measured according to ISO 19403-2:2017 is adopted as the water contact angle. In the case where the metal oxide layer 130 is subjected to reverse sputtering as a plasma treatment, the water contact angle is 20° or less. Furthermore, in the case where the metal oxide layer 130 is etched by the inductively coupled plasma, the water contact angle is 15° or less. In addition, the lower measurement limit of the water contact angle is 2°.

Furthermore, when the plasma treatment is performed on the metal oxide layer 130 using argon gas, for example, Ar atoms (atomic %) are contained in the surface portion of the metal oxide layer 130. In this case, Ar atoms (atomic %) contained in the surface of the metal oxide layer 130 means that Ar atoms are detected in an X-ray photoelectron spectroscopy (XPS) analysis of the surface of the metal oxide layer 130, that is, are equal to or higher than the lower limit of detection. Although the Ar concentration on the surface of the metal oxide layer 130 determined by the XPS analysis may be equal to or higher than the lower limit of detection, it is preferably equal to or higher than the lower limit of detection, but is preferably 1 atomic % or more. The upper limit of the Ar concentration of the metal oxide layer 130 is not particularly specified, but is preferably, for example, 3 atomic % or less. As a result, even if Ar atoms are contained in the metal oxide layer 130, the effect on the physical properties of the oxide semiconductor layer 140 can be reduced. For example, after the plasma treatment using the argon gas is performed, Ar atoms on the surface of the metal oxide layer 130 increase by 1 atomic % or more. Furthermore, in the case where the plasma treatment is performed using another rare gas, atoms of the rare gas used for the plasma treatment are contained on the surface of the metal oxide layer 130.

The surface of the metal oxide layer 130 may be removed by the plasma treatment. For example, the amount of the surface of the metal oxide layer 130 to be removed is 1 nm or more and 10 nm or less, or 1 nm or more and 5 nm or less.

In addition, the surface roughness of the metal oxide layer 130 may be reduced by the plasma treatment. For example, the surface roughness (for example, arithmetic mean roughness (Ra)) of the metal oxide layer 130 may be 1 nm or less. The surface roughness can be evaluated using an atomic force microscope (AFM).

A thickness of the metal oxide layer 130 after the plasma treatment is 1 nm or more and 50 nm or less, 1 nm or more and 30 nm or less, 1 nm or more and 20 nm or less, or 1 nm or more and 10 nm or less.

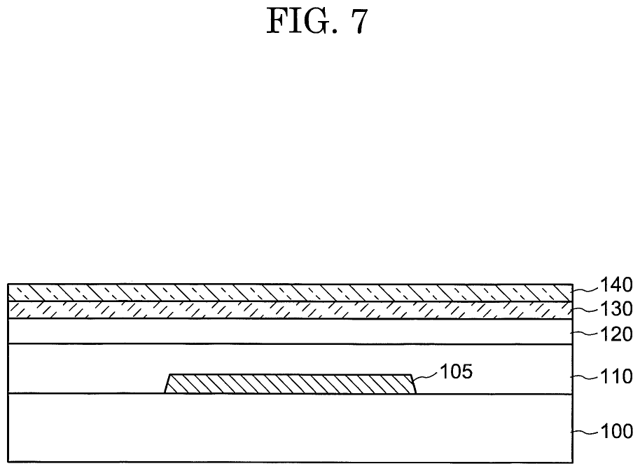

As shown in FIG. 3 and FIG. 7, the oxide semiconductor layer 140 is formed on the plasma-treated metal oxide layer 130 (“OS deposition” in step S1004 of FIG. 3).

For example, the thickness of the oxide semiconductor layer 140 is 10 nm or more and 100 nm or less, 15 nm or more and 70 nm or less, or 20 nm or more and 40 nm or less. In the present embodiment, an oxide containing indium (In) and gallium (Ga) is used as the oxide semiconductor layer 140. The oxide semiconductor layer 140 before the heat treatment (OS annealing) described later is amorphous.

In the case where the oxide semiconductor layer 140 is crystallized by the OS annealing described later, the oxide semiconductor layer 140 after the deposition and before the OS annealing is preferably amorphous (a state in which crystalline components of the oxide semiconductor are small). That is, the oxide semiconductor layer 140 is preferably formed under the condition that the oxide semiconductor layer 140 immediately after the deposition does not crystallize as much as possible. For example, in the case where the oxide semiconductor layer 140 is deposited by the sputtering method, the oxide semiconductor layer 140 is deposited in a state where a temperature of an object to be deposited (the substrate 100 and the structure formed thereon) is controlled.

When the deposition is performed on the object to be deposited by the sputtering method, ions generated in the plasma and atoms recoiled by a sputtering target collide with the object to be deposited. Therefore, the temperature of the object to be deposited increases with the deposition process. When the temperature of the object to be deposited during the deposition process increases, microcrystals are contained in the oxide semiconductor layer 140 immediately after the deposition. The crystallization by the subsequent OS annealing is inhibited by the microcrystals. In order to control the temperature of the object to be deposited as described above, for example, the deposition may be performed while cooling the object to be deposited. For example, the object to be deposited may be cooled from the surface opposite to the surface to be deposited so that the temperature of the surface to be deposited of the object to be deposited (hereinafter, referred to as “deposition temperature”) is 100° C. or lower, 70° C. or lower, 50° C. or lower, or 30° C. or lower. As described above, the deposition of the oxide semiconductor layer 140 while cooling the object to be deposited makes it possible to form the oxide semiconductor layer 140 with few crystalline components immediately after the deposition.

In the present embodiment, the plasma treatment is performed on the surface of the metal oxide layer 130 before the deposition of the oxide semiconductor layer 140. As a result, the surface of the metal oxide layer 130 is modified. Hydroxyl groups and water at the modified surface of the metal oxide layer 130 can be reduced. When the oxide semiconductor layer 140 is deposited, the atoms constituting the oxide semiconductor layer 140 are easily bonded to the metal oxide layer 130, so that the interface state density at the interface between the metal oxide layer 130 and the oxide semiconductor layer 140 can be reduced.

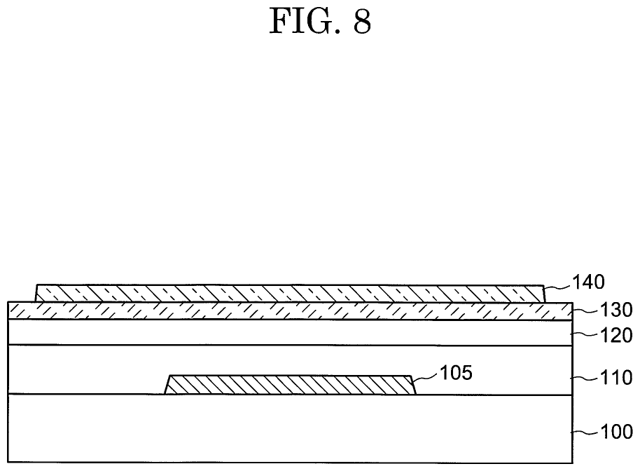

As shown in FIG. 3 and FIG. 8, a pattern of the oxide semiconductor layer 140 is formed (“OS pattern formation” in step S1005 of FIG. 3). Although not shown, a resist mask is formed on the oxide semiconductor layer 140, and the oxide semiconductor layer 140 is etched using the resist mask. Wet etching may be used, or dry etching may be used as the etching of the oxide semiconductor layer 140. The wet etching may be performed using an acidic etchant. For example, oxalic acid or hydrofluoric acid may be used as the etchant.

After the oxide semiconductor layer 140 is patterned, the heat treatment (OS annealing) is performed on the oxide semiconductor layer 140 (“OS annealing” in step S1006 of FIG. 3). In the present embodiment, the oxide semiconductor layer 140 is crystallized by the OS annealing.

In the present embodiment, the surface of the metal oxide layer 130 is modified. The oxide semiconductor layer 140 with few crystalline components is deposited on the modified surface of the metal oxide layer 130. Thereafter, by performing the OS annealing, when the oxide semiconductor layer 140 is crystallized, it is possible to suppress the crystallization from being inhibited by the hydroxyl groups or water at the interface between the metal oxide layer 130 and the oxide semiconductor layer 140. That is, the interface state density at the interface between the metal oxide layer 130 and the oxide semiconductor layer 140 can be further reduced.

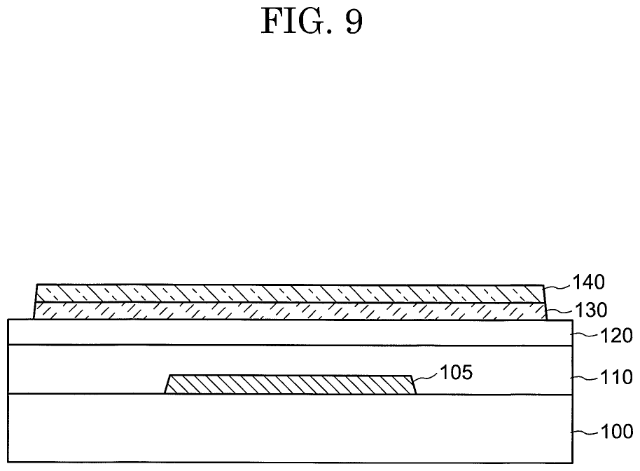

As shown in FIG. 3 and FIG. 9, a pattern of the metal oxide layer 130 is formed (“AlOx pattern formation” in step S1007 of FIG. 3). The metal oxide layer 130 is etched using the oxide semiconductor layer 140 patterned in the above-described process as a mask. Wet etching may be used, or dry etching may be used as the etching of the metal oxide layer 130. For example, dilute hydrofluoric acid (DHF) is used as the wet etching. As described above, a photolithography process can be omitted by etching the metal oxide layer 130 using the oxide semiconductor layer 140 as a mask.

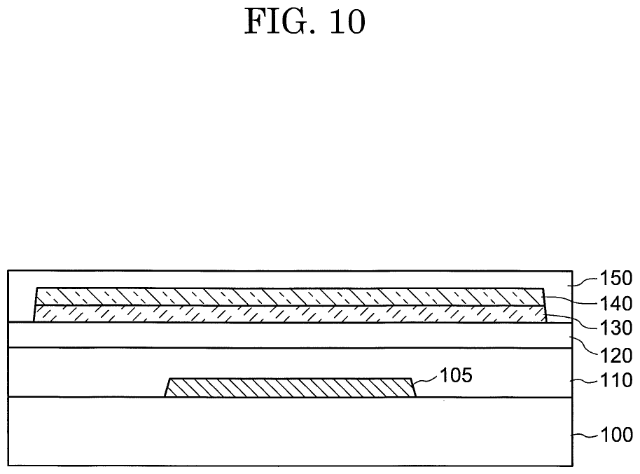

As shown in FIG. 3 and FIG. 10, the gate insulating layer 150 is formed (“GI formation” in step S1008 of FIG. 3). For example, silicon oxide is formed as the gate insulating layer 150. The gate insulating layer 150 is formed by the CVD method. For example, the gate insulating layer 150 may be deposited at a deposition temperature of 350° C. or higher in order to form the insulating layer with few defects as described above as the gate insulating layer 150. For example, a thickness of the gate insulating layer 150 is 50 nm or more and 300 nm or less, 60 nm or more and 200 nm or less, or 70 nm or more and 150 nm or less. After the gate insulating layer 150 is deposited, an oxygen-implanting process may be performed on a portion of the gate insulating layer 150.

The heat treatment (oxidation annealing) is performed to supply oxygen to the oxide semiconductor layer 140 in a state where the gate insulating layer 150 is deposited on the oxide semiconductor layer 140 (“Oxidation annealing” in step S1009 of FIG. 3). In the process from the deposition of the oxide semiconductor layer 140 to the deposition of the gate insulating layer 150 on the oxide semiconductor layer 140, a large amount of oxygen deficiencies occur in the upper surface 141 and the side surface 143 of the oxide semiconductor layer 140. Oxygen released from the gate insulating layers 120 and 150 is supplied to the oxide semiconductor layer 140 by the above-described oxidation annealing, and the oxygen deficiencies are repaired.

Oxygen released from the gate insulating layer 120 is blocked by the metal oxide layer 130 by the oxidation annealing. Therefore, oxygen is less likely to be supplied to the bottom surface 142 of the oxide semiconductor layer 140. The oxygen emitted from the gate insulating layer 120 diffuses from a region where the metal oxide layer 130 is not formed to the gate insulating layer 150 arranged on the gate insulating layer 120, and reaches the oxide semiconductor layer 140 via the gate insulating layer 150. As a result, the oxygen emitted from the gate insulating layer 120 is less likely to be supplied to the bottom surface 142 of the oxide semiconductor layer 140, and is mainly supplied to the side surface 143 and the upper surface 141 of the oxide semiconductor layer 140. In addition, the oxygen released from the gate insulating layer 150 is supplied to the upper surface 141 and the side surface 143 of the oxide semiconductor layer 140 by the oxidation annealing. The oxidation annealing may release hydrogen from the gate insulating layers 110 and 120, which is blocked by the metal oxide layer 130.

As described above, by the process of the oxidation annealing, it is possible to supply oxygen to the upper surface 141 and the side surface 143 of the oxide semiconductor layer 140 having a large amount of oxygen deficiencies while suppressing the supply of oxygen to the bottom surface 142 of the oxide semiconductor layer 140 having a small amount of oxygen deficiencies.

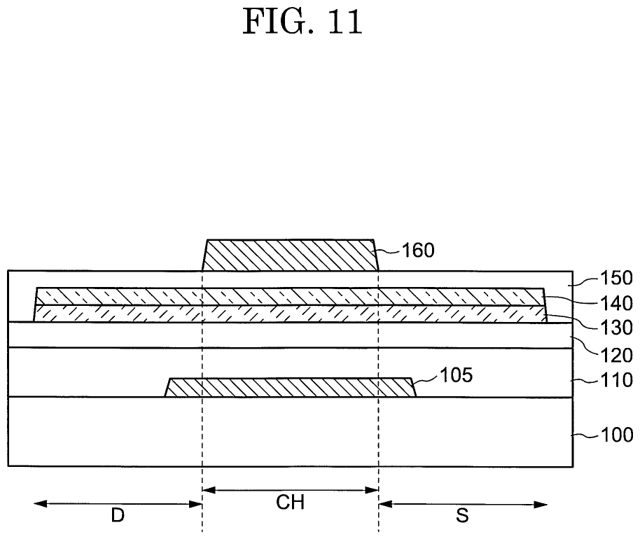

As shown in FIG. 3 and FIG. 11, the gate electrode 160 is formed (“GE formation” in step S1010 of FIG. 3). The gate electrode 160 is formed by forming a conductive film by the sputtering method or the atomic layer deposition method, and patterning the conductive film through the photolithography process.

With the gate electrode 160 patterned, the resistance of the source region S and the drain region D of the oxide semiconductor layer 140 is reduced (“SD resistance reduction” in step S1011 of FIG. 3). Specifically, an impurity is implanted into the oxide semiconductor layer 140 from the gate electrode 160 side via the gate insulating layer 150 by an ion implantation. For example, argon (Ar), phosphorus (P), and boron (B) are implanted into the oxide semiconductor layer 140 by the ion implantation. Oxygen deficiencies are formed in the oxide semiconductor layer 140 by the ion implantation, thereby reducing the resistance of the oxide semiconductor layer 140. Since the gate electrode 160 is arranged above the oxide semiconductor layer 140 that functions as the channel region CH of the semiconductor device 10, impurities are not implanted into the oxide semiconductor layer 140 in the channel region CH.

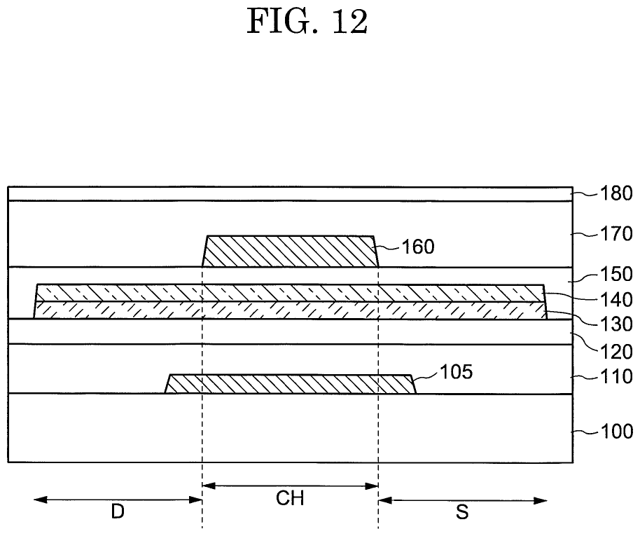

As shown in FIG. 3 and FIG. 12, the insulating layers 170 and 180 are formed as an interlayer film on the gate insulating layer 150 and the gate electrode 160 (“Interlayer film deposition” in step S1012 of FIG. 3). The insulating layers 170 and 180 are formed by the CVD method. For example, silicon nitride is formed as the insulating layer 170, and silicon oxide is formed as the insulating layer 180. The materials used as the insulating layers 170 and 180 are not limited to the above. A thickness of the insulating layer 170 is 50 nm or more and 500 nm or less. A thickness of the insulating layer 180 is 50 nm or more and 500 nm or less.

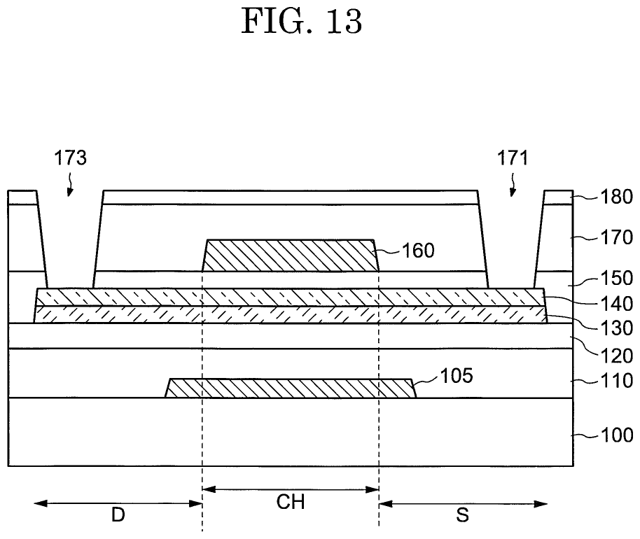

As shown in FIG. 3 and FIG. 13, the openings 171 and 173 are formed in the gate insulating layer 150 and the insulating layers 170 and 180 (“Contact hole formation” in step S1013 of FIG. 3). The opening 171 exposes the oxide semiconductor layer 140 in the source region S. The oxide semiconductor layer 140 in the drain region D is exposed by the opening 173. Forming the source-drain electrode 200 on the oxide semiconductor layer 140 and on the insulating layer 180 exposed by the openings 171 and 173 (“SD formation” in step S1014 of FIG. 3) completes the semiconductor device 10 shown in FIG. 1.

As a result, the electrical characteristics having the mobility of 30 cm²/Vs or more, 35 cm²/Vs or more, preferably 40 cm²/Vs or more can be obtained in a range where the channel length L of the channel region CH in the semiconductor device 10 is 2 μm or more and 4 μm or less, and the channel width of the channel region CH is 2 μm or more and 25 μm or less. The mobility in the present embodiment is the field-effect mobility in a saturated region of the semiconductor device 10. Specifically, the mobility means the maximum value of the field-effect mobility in a region where a potential difference (Vd) between the source electrode and the drain electrode is greater than a value (Vg−Vth) obtained by subtracting a threshold voltage (Vth) of the semiconductor device 10 from a voltage (Vg) supplied to the gate electrode.

In the case of the top-gate transistor of the present embodiment, the interface between the metal oxide layer 130 and the oxide semiconductor layer 140 is the back-channel side of the transistor. By reducing the interface state density at the interface on the back-channel side, it is possible to suppress the electron from being trapped in the interface state. As a result, degradation of the transistor can be suppressed by the reliability test. That is, the reliability of the semiconductor device 10 can be improved.

### First Modification of First Embodiment

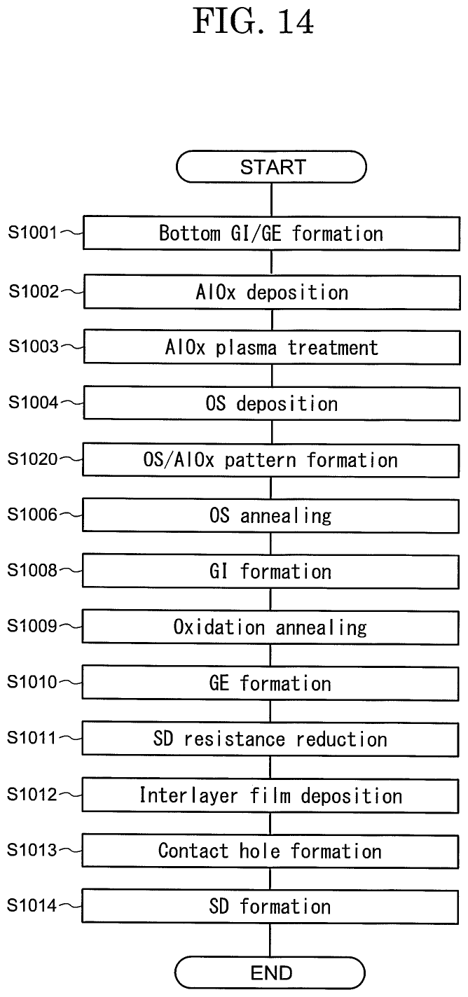

A first modification of the present embodiment will be described with reference to FIG. 14 to FIG. 16. Although a configuration of the semiconductor device 10 according to the first modification is similar to that of FIG. 1, the manufacturing method thereof is different from that of FIG. 3 to FIG. 13. In the following description, the steps common to the manufacturing method shown in FIG. 3 to FIG. 13 will be omitted, and the manufacturing method will be described mainly according to the difference.

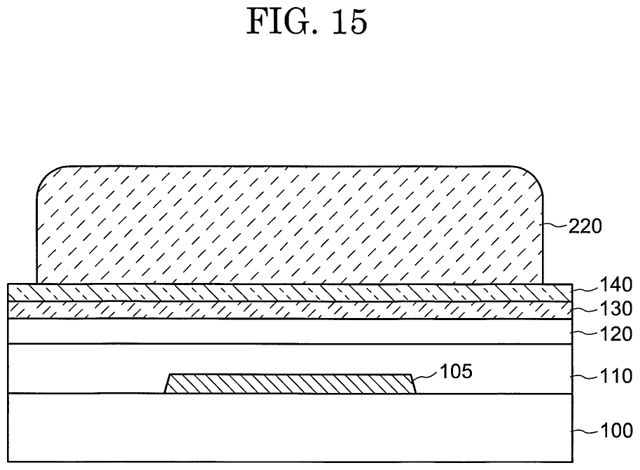

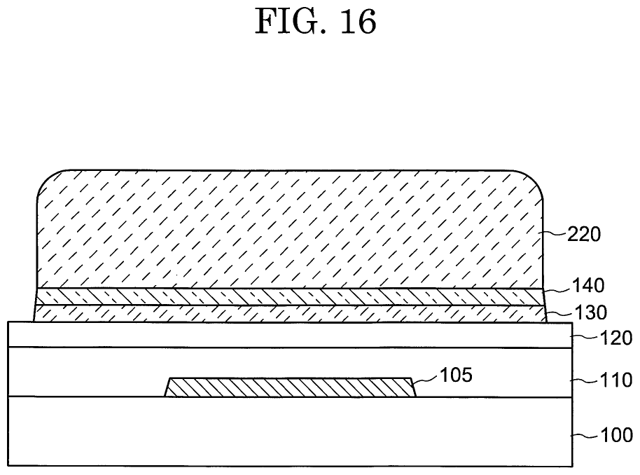

FIG. 14 is a sequence diagram showing a method for manufacturing a semiconductor device according to a modification of the embodiment. FIG. 15 and FIG. 16 are cross-sectional views showing a method for manufacturing a semiconductor device according to a modification of an embodiment of the present invention. As shown in FIG. 14, in the first modification, the patterns of the metal oxide layer 130 and the oxide semiconductor layer 140 are collectively formed (“OS/AlOx pattern formation” in step S1020).

As shown in FIG. 15, after the metal oxide layer 130 and the oxide semiconductor layer 140 are deposited, a resist mask 220 is formed on the oxide semiconductor layer 140. Then, as shown in FIG. 16, the patterns of the metal oxide layer 130 and the oxide semiconductor layer 140 are formed using the resist mask 220. Wet etching may be used, or dry etching may be used as the etching of the metal oxide layer 130 and the oxide semiconductor layer 140. In the case where the metal oxide layer 130 and the oxide semiconductor layer 140 are etched by wet etching, an etchant similar to that described above can be used. In the first modification, the OS annealing is performed in a state where the patterns of the metal oxide layer 130 and the oxide semiconductor layer 140 are formed (step S1006). Since the subsequent steps S1008 to S1014 are similar to those in FIG. 3, detailed explanation thereof will be omitted.

### Second Modification of First Embodiment

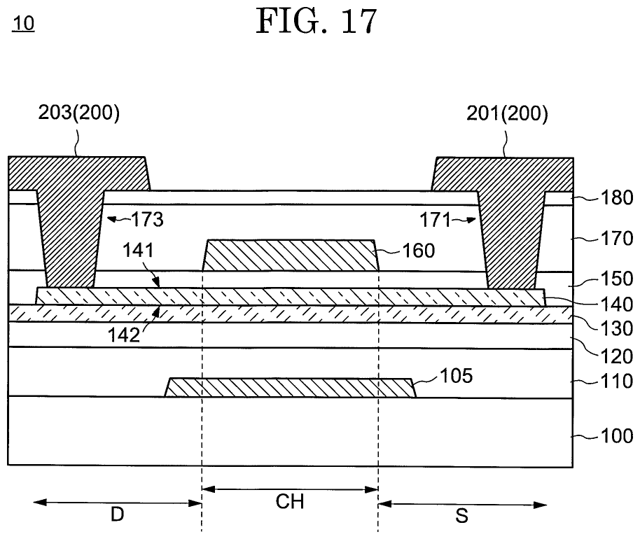

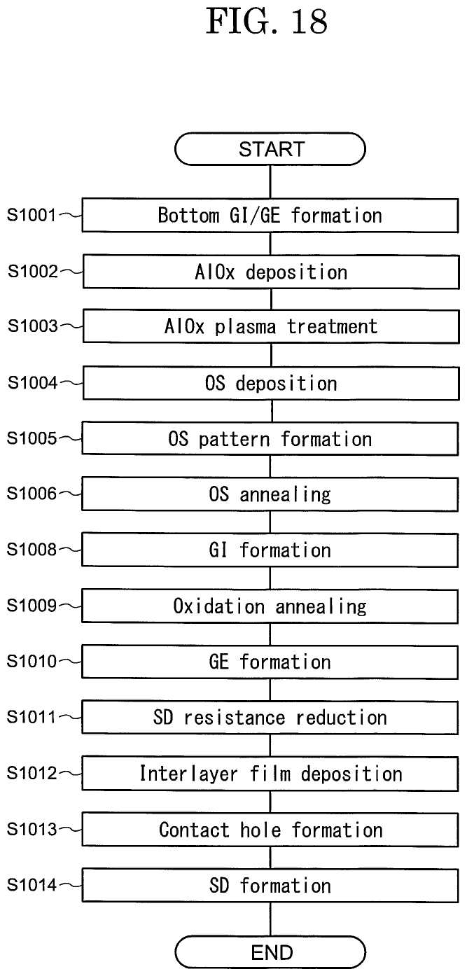

A second modification of the present embodiment will be described with reference to FIG. 17 and FIG. 18. A structure and manufacturing method of the semiconductor device 10 according to the second modification are different from that of FIG. 1 and FIG. 3 to FIG. 13. In the following description, the steps common to the manufacturing method shown in FIG. 1 and FIG. 3 to FIG. 13 will be omitted, and the manufacturing method will be described mainly according to the difference.

FIG. 17 is a cross-sectional view showing an outline of a semiconductor device according to a modification of an embodiment of the present invention. FIG. 18 is a sequence diagram showing a method for manufacturing a semiconductor device according to a modification of an embodiment.

As shown in FIG. 17, a structure of the semiconductor device 10 according to the second modification is similar to the structure of the semiconductor device 10 shown in FIG. 1, but differs from the structure of the semiconductor device 10 shown in FIG. 1 in that the pattern of the metal oxide layer 130 is not formed. That is, in the second modification, the metal oxide layer 130 extends outside the pattern of the oxide semiconductor layer 140. The metal oxide layer 130 is in contact with the gate insulating layer 150 outside the pattern of the oxide semiconductor layer 140.

As shown in FIG. 18, the method for manufacturing the semiconductor device 10 according to the second modification is similar to the method for manufacturing the semiconductor device 10 shown in FIG. 3, but is different from the method for manufacturing the semiconductor device 10 shown in FIG. 3 in that the process of patterning the metal oxide layer 130 (step S1007 in FIG. 3) is omitted. Since the subsequent steps S1008 to S1014 are similar to those in FIG. 3, detailed explanation thereof will be omitted.

### Third Modification of First Embodiment

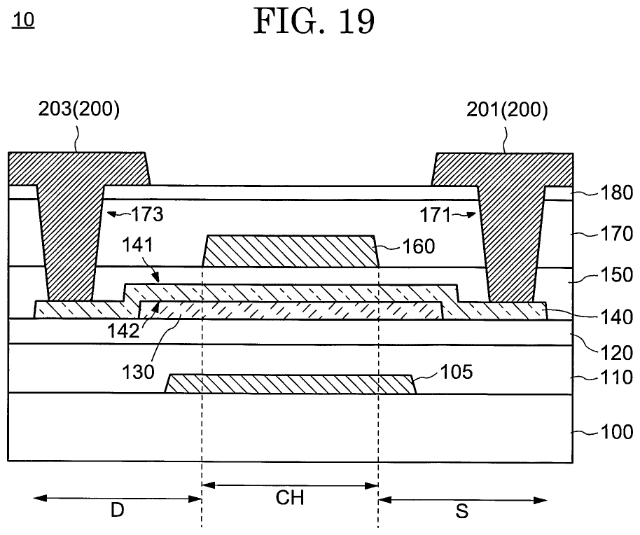

A third modification of the present embodiment will be described with reference to FIG. 19 to FIG. 23. A structure and manufacturing method of the semiconductor device 10 according to the third modification are different from those of FIG. 1 to FIG. 13. In the following description, the steps common to the manufacturing method shown in FIG. 1 to FIG. 13 will be omitted, and the manufacturing method will be mainly described according to the difference.

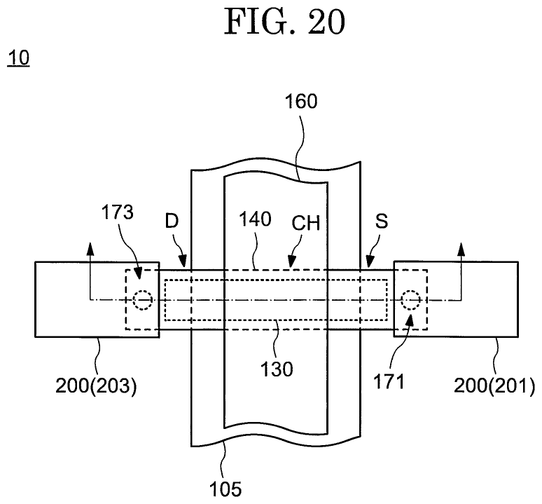

FIG. 19 is a cross-sectional view showing an outline of the semiconductor device 10 according to an embodiment of the present invention. FIG. 20 is a plan view showing an outline of the semiconductor device 10 according to an embodiment of the present invention.

As shown in FIG. 19 and FIG. 20, the structure of the semiconductor device 10 according to the third modification is similar to the structure of the semiconductor device 10 shown in FIG. 1 and FIG. 2, but is different from the structure of the semiconductor device 10 shown in FIG. 1 in that the pattern of the metal oxide layer 130 is different from the pattern of the oxide semiconductor layer 140. Specifically, in the cross-sectional view of FIG. 19, the pattern of the oxide semiconductor layer 140 extends outside the pattern of the metal oxide layer 130. That is, the oxide semiconductor layer 140 extends beyond the pattern of the metal oxide layer 130. The oxide semiconductor layer 140 is in contact with the gate insulating layer 120 outside the pattern of the metal oxide layer 130. The gate insulating layer 120 may be referred to as a “first insulating layer.”

The source-drain electrode 200 is in contact with the oxide semiconductor layer 140 in a region where the metal oxide layer 130 is not arranged. The pattern of the metal oxide layer 130 is positioned inside the pattern of the oxide semiconductor layer 140 in a plan view of FIG. 20. The openings 171 and 173 are arranged in a region that does not overlap the patterned metal oxide layer 130.

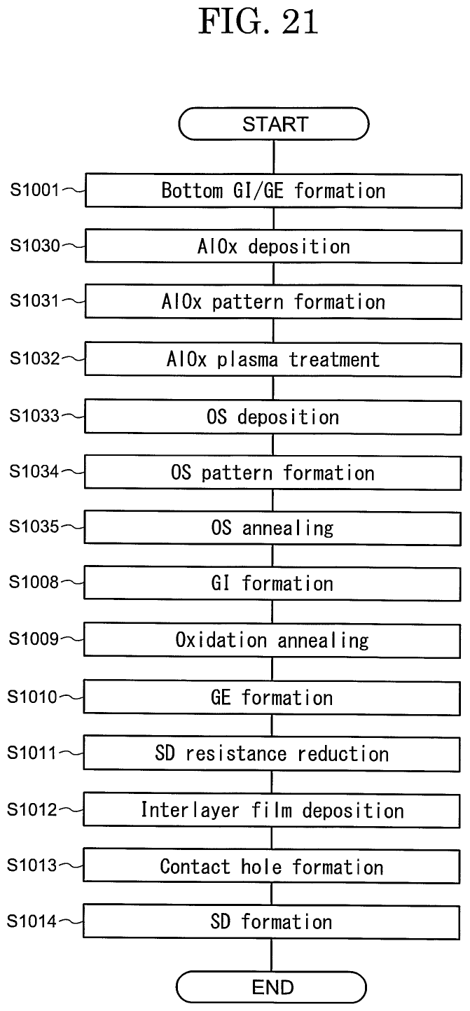

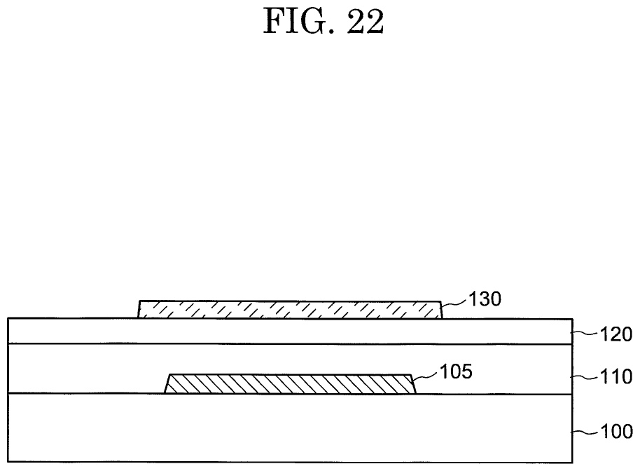

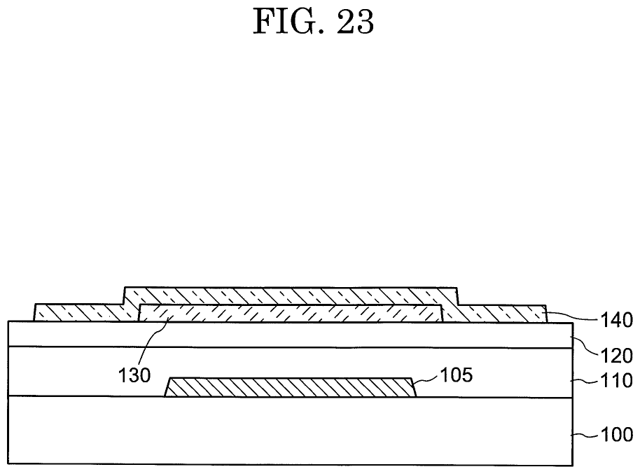

FIG. 21 is a sequence diagram showing a method for manufacturing a semiconductor device according to an embodiment of the present invention. FIG. 22 and FIG. 23 are cross-sectional views showing a method for manufacturing a semiconductor device according to an embodiment of the present invention. As shown in FIG. 21, in the third modification, after the pattern of the metal oxide layer 130 is formed (“AlOx deposition” in step S1030 and “AlOx pattern formation” in step S1031), the metal oxide layer 130 is plasma-treated (step S1032). Thereafter, the pattern of the oxide semiconductor layer 140 is formed (“OS deposition” in step S1033 and “OS pattern formation” in step S1034). Unlike FIG. 3, the OS annealing (“OS annealing” in step S1035) is performed after the gate insulating layer 150 is formed.

As shown in FIG. 22, the metal oxide layer 130 is deposited on the gate insulating layer 120 (step S1030), and the pattern of the metal oxide layer 130 is formed (step S1031). The pattern formation (etching) of the metal oxide layer 130 is performed in a similar method as described above. After that, the plasma treatment is performed on the patterned metal oxide layer 130 (step S1032).

As shown in FIG. 23, the oxide semiconductor layer 140 is deposited on the patterned metal oxide layer 130 (step S1033), and the pattern of the oxide semiconductor layer 140 is formed (step S1034). The pattern formation (etching) of the oxide semiconductor layer 140 is performed in a similar method as described above. After that, the OS annealing is performed as shown in FIG. 23 (step S1035). Since the subsequent steps S1008 to S1014 are similar to those in FIG. 3, detailed explanation thereof will be omitted.

In the present modification, the plasma treatment is performed on the pattern of the metal oxide layer 130. That is, the surface modification is performed not only on the surface but also on the side surface of the metal oxide layer 130. As a result, the oxygen deficiencies formed in the oxide semiconductor layer 140 can be reduced even at the interface between the side surface of the metal oxide layer 130 and the side surface of the oxide semiconductor layer 140.

As described above, the semiconductor device 10 according to the first modification to the third modification of the present embodiment can achieve the same advantages as those of the present embodiment.

### Second Embodiment

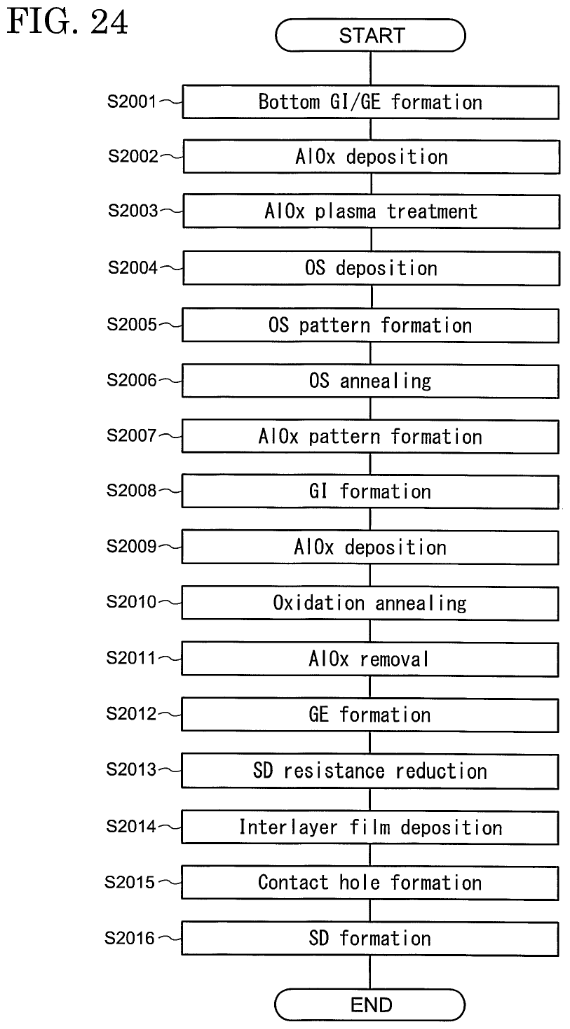

A semiconductor device according to an embodiment of the present invention will be described with reference to FIG. 24 to FIG. 35.

### [Configuration of Semiconductor Device 10]

A configuration of the semiconductor device 10 according to the present embodiment is similar to that of the first embodiment. Therefore, the semiconductor device 10 according to the present embodiment will be described with reference to FIG. 1 and FIG. 2. The semiconductor device 10 according to the present embodiment is different from the semiconductor device 10 according to the first embodiment in the manufacturing method. Therefore, in the present embodiment, the description of the configuration of the semiconductor device 10 will be omitted, and the manufacturing method thereof will be described. In the following description, a material similar to that of the metal oxide layer 130 is used as a metal oxide layer 190.

### [Method for Manufacturing Semiconductor Device 10]

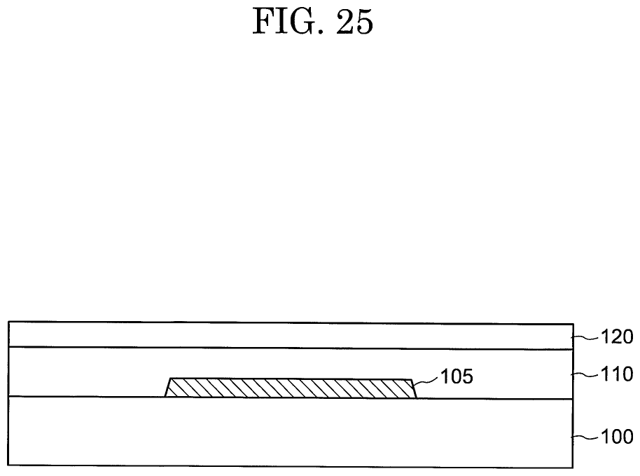

A method for manufacturing the semiconductor device 10 according to an embodiment of the present invention will be described with reference to FIG. 24 to FIG. 35. FIG. 24 is a sequence diagram showing a method for manufacturing the semiconductor device 10 according to an embodiment of the present invention. FIG. 25 to FIG. 35 are cross-sectional views showing a method for manufacturing the semiconductor device 10 according to an embodiment of the present invention. In the following description of the manufacturing method, a method for manufacturing the semiconductor device 10 in which aluminum oxide is used as the metal oxide layers 130 and 190 will be described.

As shown in FIG. 24 and FIG. 25, the gate electrode 105 is formed as a bottom gate on the substrate 100, and the gate insulating layers 110 and 120 are formed on the gate electrode 105 (“Bottom GI/GE formation” in step S2001 of FIG. 24). For example, silicon nitride is formed as the gate insulating layer 110. For example, silicon oxide is formed as the gate insulating layer 120. The gate insulating layers 110 and 120 are formed by the CVD method.

The use of silicon nitride as the gate insulating layer 110 allows the gate insulating layer 110 to block impurities that diffuse, for example, from the substrate 100 toward the oxide semiconductor layer 140. The silicon oxide used as the gate insulating layer 120 is silicon oxide having a physical property of releasing oxygen by the heat treatment.

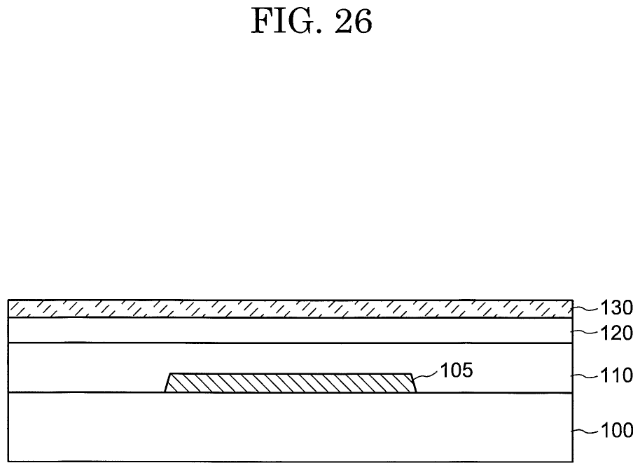

As shown in FIG. 24 and FIG. 26, the metal oxide layer 130 and the oxide semiconductor layer 140 are formed on the gate insulating layer 120 (“AlOx deposition” in step S2002 of FIG. 24). The metal oxide layer 130 is deposited by the sputtering method or the atomic layer deposition method (ALD).

For example, the thickness of the metal oxide layer 130 at the time of deposition is 2 nm or more and 51 nm or less, 2 nm or more and 31 nm or less, 2 nm or more and 21 nm or less, or 2 nm or more and 11 nm or less. The thickness of the metal oxide layer 130 may be appropriately set according to the method of the plasma treatment described later. In the present embodiment, aluminum oxide is used as the metal oxide layer 130. Aluminum oxide has a high barrier property against gases such as oxygen and hydrogen. The metal oxide layer 130 is deposited by sputtering. In the present embodiment, the aluminum oxide used as the metal oxide layer 130 blocks hydrogen and oxygen released from the gate insulating layer 120 and suppresses the released hydrogen and oxygen from reaching the oxide semiconductor layer 140.

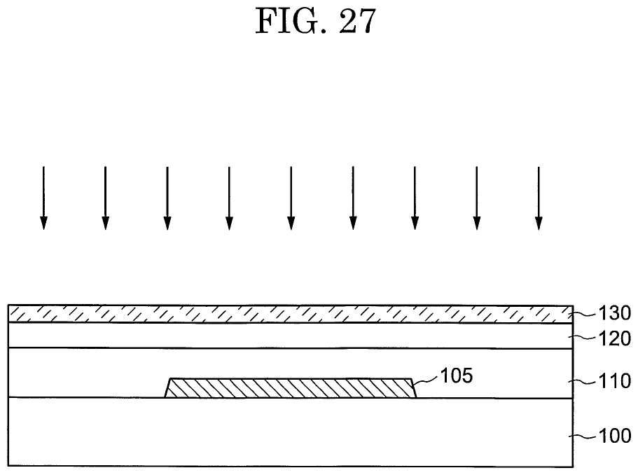

As shown in FIG. 24 and FIG. 27, the plasma treatment is performed on the metal oxide layer 130 (“AlOx plasma treatment” in step S2003 of FIG. 24). The etching by reverse sputtering or inductively coupled plasma described in the first embodiment can be applied to the plasma treatment.

The surface of the metal oxide layer 130 is modified by performing the plasma treatment on the metal oxide layer 130. For example, the water contact angle of the surface of the metal oxide layer 130 after the plasma treatment is 20° or less, preferably 15° or less, and more preferably 10° or less.

In addition, when the plasma treatment is performed on the metal oxide layer 130 using argon gas, for example, Ar atoms (atomic %) is contained in the surface of the metal oxide layer 130. The Ar concentration of the metal oxide layer 130 is 1 atomic % or more and 3 atomic % or less.

The surface of the metal oxide layer 130 may be removed by the plasma treatment. For example, the amount of the metal oxide layer 130 to be removed is 1 nm or more and 10 nm or less, or 1 nm or more and 5 nm or less.

In addition, the surface roughness of the metal oxide layer 130 may be reduced by the plasma treatment. For example, the surface roughness (for example, arithmetic mean roughness (Ra)) of the metal oxide layer 130 may be 1 nm or less. The surface roughness can be evaluated using the atomic force microscope (AFM).

The thickness of the metal oxide layer 130 after the plasma treatment is 1 nm or more and 50 nm or less, 1 nm or more and 30 nm or less, 1 nm or more and 20 nm or less, or 1 nm or more and 10 nm or less.

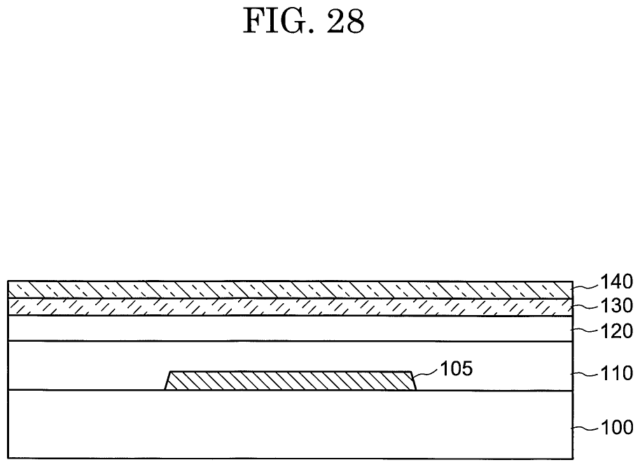

As shown in FIG. 24 and FIG. 28, the oxide semiconductor layer 140 is deposited on the plasma-treated metal oxide layer 130 (“OS deposition” in step S2004 of FIG. 24).

For example, the thickness of the oxide semiconductor layer 140 is 10 nm or more and 100 nm or less, 15 nm or more and 70 nm or less, or 20 nm or more and 40 nm or less. In the present embodiment, an oxide containing indium (In) and gallium (Ga) is used as the oxide semiconductor layer 140. The oxide semiconductor layer 140 before the OS annealing described later is amorphous.

In the case where the oxide semiconductor layer 140 is crystallized by the OS annealing described later, the oxide semiconductor layer 140 after the deposition and before the OS annealing is preferably amorphous (a state in which crystalline components of the oxide semiconductor are small). That is, the oxide semiconductor layer 140 is preferably formed under the condition that the oxide semiconductor layer 140 immediately after the deposition does not crystallize as much as possible. For example, in the case where the oxide semiconductor layer 140 is deposited by the sputtering method, the oxide semiconductor layer 140 is deposited in a state where a temperature of the object to be deposited (the substrate 100 and the structure formed thereon) is controlled.

When the deposition is performed on the object to be deposited by the sputtering method, ions generated in the plasma and atoms recoiled by the sputtering target collide with the object to be deposited. Therefore, the temperature of the object to be deposited increases with the deposition process. When the temperature of the object to be deposited during the deposition process increases, microcrystals are contained in the oxide semiconductor layer 140 immediately after the deposition. The crystallization by the subsequent OS annealing is inhibited by the microcrystals. In order to control the temperature of the object to be deposited as described above, for example, the deposition may be performed while cooling the object to be deposited. For example, the object to be deposited may be cooled from the surface opposite to the surface to be deposited so that the temperature of the surface to be deposited of the object to be deposited is 100° C. or lower, 70° C. or lower, 50° C. or lower, or 30° C. or lower. As described above, the deposition of the oxide semiconductor layer 140 while cooling the object to be deposited makes it possible to form the oxide semiconductor layer 140 with few crystalline components immediately after the deposition.

In the present embodiment, the plasma treatment is performed on the surface of the metal oxide layer 130 before the deposition of the oxide semiconductor layer 140. As a result, the surface of the metal oxide layer 130 is modified. Hydroxyl groups and water at the modified surface of the metal oxide layer 130 can be reduced. When the oxide semiconductor layer 140 is deposited, the atoms constituting the oxide semiconductor layer 140 are easily bonded to the metal oxide layer 130, so that the interface state density at the interface between the metal oxide layer 130 and the oxide semiconductor layer 140 can be reduced.

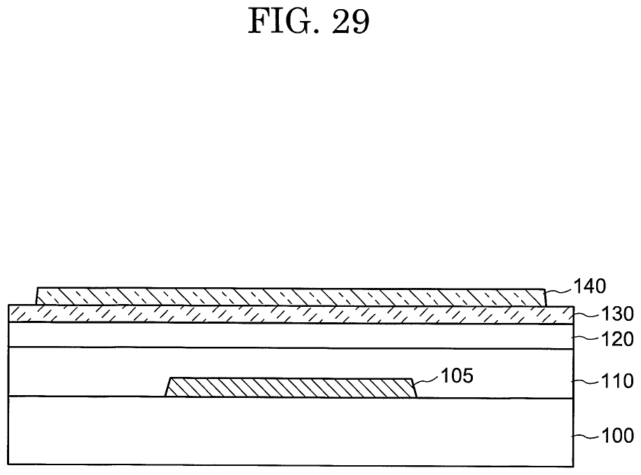

As shown in FIG. 24 and FIG. 29, the pattern of the oxide semiconductor layer 140 is formed (“OS pattern formation” in step S2005 of FIG. 24). Although not shown, a resist mask is formed on the oxide semiconductor layer 140, and the oxide semiconductor layer 140 is etched using the resist mask. Wet etching may be used, or dry etching may be used as the etching of the oxide semiconductor layer 140. The wet etching may be performed using an acidic etchant. For example, oxalic acid or hydrofluoric acid may be used as the etchant.

After the oxide semiconductor layer 140 is patterned, the heat treatment (OS annealing) is performed on the oxide semiconductor layer 140 (“OS annealing” in step S2006 of FIG. 24). In the present embodiment, the oxide semiconductor layer 140 is crystallized by the OS annealing.

In the present embodiment, the surface of the metal oxide layer 130 is modified. The oxide semiconductor layer 140 with few crystalline components is deposited on the modified surface of the metal oxide layer 130. Thereafter, by performing the OS annealing, when the oxide semiconductor layer 140 is crystallized, it is possible to suppress the crystallization from being inhibited by the hydroxyl groups or water at the interface between the metal oxide layer 130 and the oxide semiconductor layer 140. That is, the interface state density at the interface between the metal oxide layer 130 and the oxide semiconductor layer 140 can be further reduced.

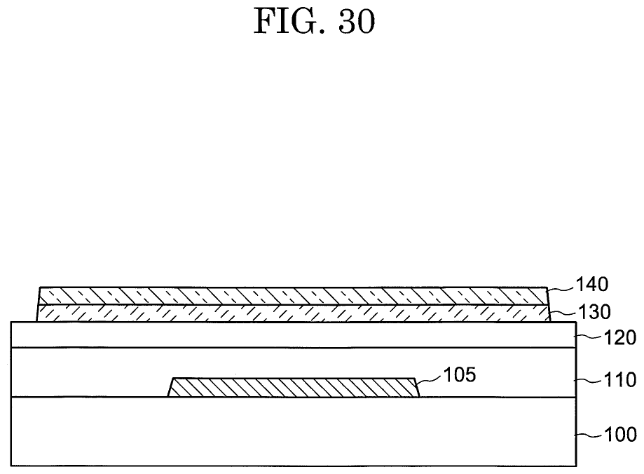

As shown in FIG. 24 and FIG. 30, the pattern of the metal oxide layer 130 is formed (“AlOx pattern formation” in step S2007 of FIG. 24). The metal oxide layer 130 is etched using the oxide semiconductor layer 140 patterned in the above-described process as a mask. Wet etching may be used, or dry etching may be used as the etching of the metal oxide layer 130. For example, dilute hydrofluoric acid (DHF) is used as the wet etching. As described above, the photolithography process can be omitted by etching the metal oxide layer 130 using the oxide semiconductor layer 140 as a mask.

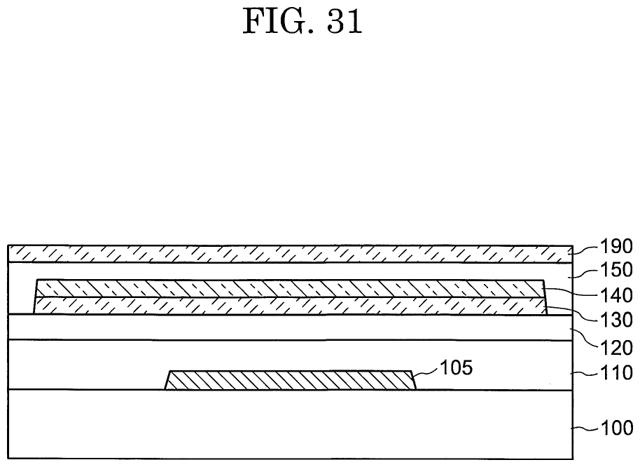

As shown in FIG. 24 and FIG. 31, the gate insulating layer 150 is formed (“GI formation” in step S2008 of FIG. 24). For example, silicon oxide is formed as the gate insulating layer 150. The gate insulating layer 150 is formed by the CVD method. For example, the gate insulating layer 150 may be deposited at a deposition temperature of 350° C. or higher in order to form the insulating layer with few defects as described above as the gate insulating layer 150. For example, the thickness of the gate insulating layer 150 is 50 nm or more and 300 nm or less, 60 nm or more and 200 nm or less, or 70 nm or more and 150 nm or less. After the gate insulating layer 150 is deposited, the oxygen-implanting process may be performed on a portion of the gate insulating layer 150. The metal oxide layer 190 is deposited on the gate insulating layer 150 (“AlOx deposition” in step S2009 of FIG. 24). The metal oxide layer 190 is deposited by the sputtering method. Oxygen is implanted into the gate insulating layer 150 by the deposition of the metal oxide layer 190.

For example, a thickness of the metal oxide layer 190 is 5 nm or more and 100 nm or less, 5 nm or more and 50 nm or less, 5 nm or more and 30 nm or less, or 7 nm or more and 15 nm or less. In the present embodiment, aluminum oxide is used as the metal oxide layer 190. Aluminum oxide has a high barrier property against gases such as oxygen and hydrogen. In the present embodiment, the aluminum oxide used as the metal oxide layer 190 suppresses the oxygen implanted into the gate insulating layer 150 from diffusing outward at the time of deposition of the metal oxide layer 190.

For example, in the case where the metal oxide layer 190 is formed by the sputtering method, a process gas used in the sputtering remains in the film of the metal oxide layer 190. For example, in the case where Ar is used as the process gas for sputtering, Ar may remain in the film of the metal oxide layer 190. The remaining Ar can be detected by a SIMS (Secondary lon Mass Spectrometry) analysis or XPS analysis on the metal oxide layer 190.

The heat treatment (oxidation anneal) is performed to supply oxygen to the oxide semiconductor layer 140 in a state where the gate insulating layer 150 is deposited on the oxide semiconductor layer 140 and the metal oxide layer 190 is deposited on the gate insulating layer 150 (“Oxidation annealing” in step S2010 of FIG. 24). In the process from the deposition of the oxide semiconductor layer 140 to the deposition of the gate insulating layer 150 on the oxide semiconductor layer 140, a large amount of oxygen deficiencies occur in the upper surface 141 and the side surface 143 of the oxide semiconductor layer 140. Oxygen released from the gate insulating layers 120 and 150 is supplied to the oxide semiconductor layer 140 by the above-described oxidation annealing, and the oxygen deficiencies are repaired.

Oxygen released from the gate insulating layer 120 is blocked by the metal oxide layer 130 by the oxidation annealing. Therefore, the oxygen is less likely to be supplied to the bottom surface 142 of the oxide semiconductor layer 140. The oxygen emitted from the gate insulating layer 120 diffuses from a region where the metal oxide layer 130 is not formed to the gate insulating layer 150 arranged on the gate insulating layer 120, and reaches the oxide semiconductor layer 140 via the gate insulating layer 150. As a result, the oxygen released from the gate insulating layer 120 is less likely to be supplied to the bottom surface 142 of the oxide semiconductor layer 140, and is mainly supplied to the side surface 143 and the upper surface 141 of the oxide semiconductor layer 140. In addition, the oxygen released from the gate insulating layer 150 is supplied to the upper surface 141 and the side surface 143 of the oxide semiconductor layer 140 by the oxidation annealing. The oxidation anneal may release hydrogen from the gate insulating layers 110 and 120, which is blocked by the metal oxide layer 130.

As described above, by the process of the oxidation annealing, it is possible to supply oxygen to the upper surface 141 and the side surface 143 of the oxide semiconductor layer 140 having a large amount of oxygen deficiencies while suppressing the supply of oxygen to the bottom surface 142 of the oxide semiconductor layer 140 having a small amount of oxygen deficiencies.

Similarly, in the above-described oxidation annealing, the oxygen implanted into the gate insulating layer 150 is blocked by the metal oxide layer 190, and is suppressed from being released into the atmosphere. Therefore, the oxygen is efficiently supplied to the oxide semiconductor layer 140 by the oxidation annealing, and the oxygen deficiencies are repaired.

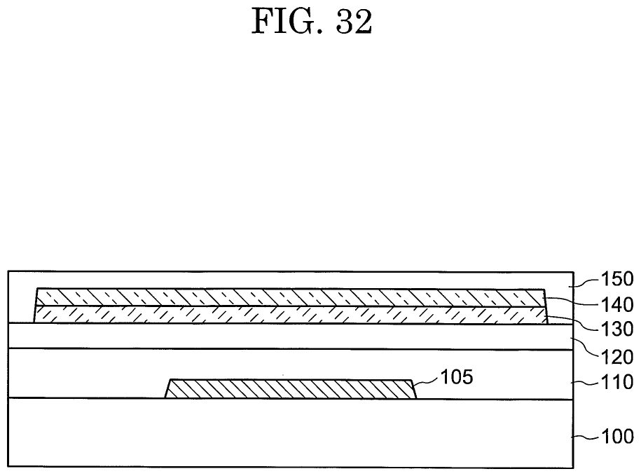

As shown in FIG. 24 and FIG. 32, after the oxidation annealing, the metal oxide layer 190 is etched (removed) (“AlOx removal” in step S2011 of FIG. 24). Wet etching may be used, or dry etching may be used as the etching of the metal oxide layer 190. For example, dilute hydrofluoric acid (DHF) is used as the wet etching.

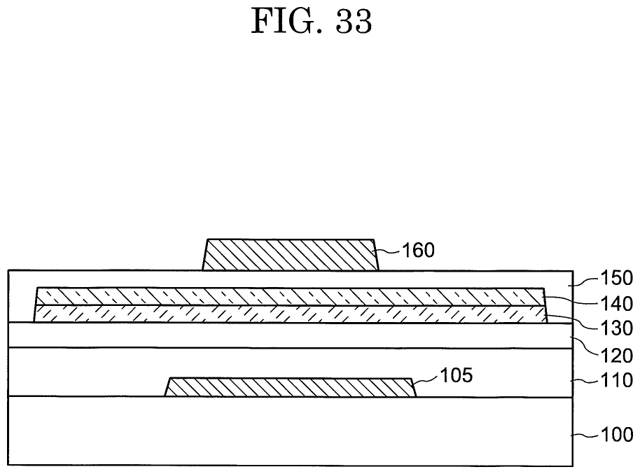

As shown in FIG. 24 and FIG. 33, the gate electrode 160 is deposited (“GE formation” in step S2012 of FIG. 24). The gate electrode 160 is deposited by the sputtering method or the atomic layer deposition method, and is patterned through the photolithography process.

With the gate electrode 160 patterned, the resistance of the source region S and the drain region D of the oxide semiconductor layer 140 is reduced (“SD resistance reduction” in step S2013 of FIG. 24). Specifically, an impurity is implanted into the oxide semiconductor layer 140 from the gate electrode 160 side via the gate insulating layer 150 by the ion implantation. For example, argon (Ar), phosphorus (P), and boron (B) are implanted into the oxide semiconductor layer 140 by the ion implantation. Oxygen deficiencies are formed in the oxide semiconductor layer 140 by the ion implantation, thereby reducing the resistance of the oxide semiconductor layer 140. Since the gate electrode 160 is arranged above the oxide semiconductor layer 140 that functions as the channel region CH of the semiconductor device 10, impurities are not implanted into the oxide semiconductor layer 140 in the channel region CH.

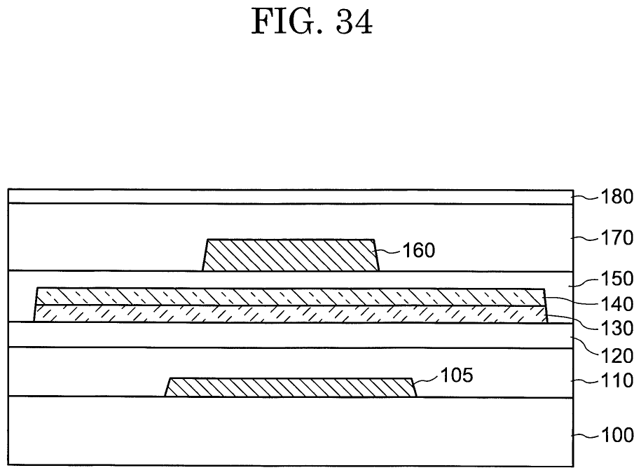

As shown in FIG. 24 and FIG. 34, the insulating layers 170 and 180 are formed as an interlayer film on the gate insulating layer 150 and the gate electrode 160 (“Interlayer film deposition” in step S2014 of FIG. 24). The insulating layers 170 and 180 are formed by the CVD method. For example, silicon nitride is formed as the insulating layer 170, and silicon oxide is formed as the insulating layer 180. The materials used as the insulating layers 170 and 180 are not limited to the above. The thickness of the insulating layer 170 is 50 nm or more and 500 nm or less. The thickness of the insulating layer 180 is 50 nm or more and 500 nm or less.

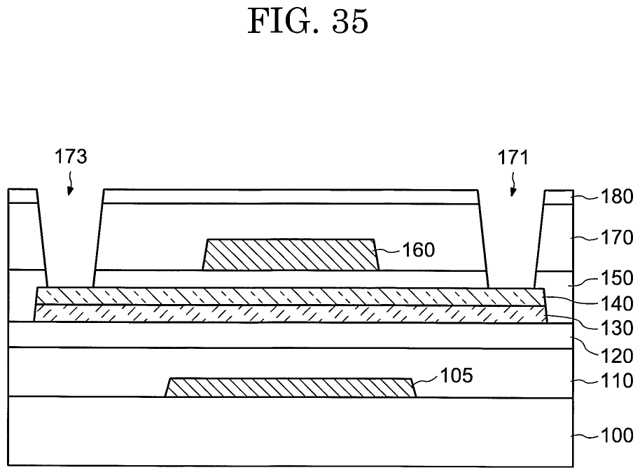

As shown in FIG. 24 and FIG. 35, the openings 171 and 173 are formed in the gate insulating layer 150 and the insulating layers 170 and 180 (“Contact hole formation” in step S2015 of FIG. 24). The opening 171 exposes the oxide semiconductor layer 140 in the source region S. The oxide semiconductor layer 140 in the drain region D is exposed by the opening 173. Forming the source-drain electrode 200 on the oxide semiconductor layer 140 and on the insulating layer 180 exposed by the openings 171 and 173 (“SD formation” in step S2016 of FIG. 24) completes the semiconductor device 10 shown in FIG. 1.

As a result, the electrical characteristics having the mobility of 30 cm²/Vs or more, 35 cm²/Vs or more, preferably 40 cm²/Vs or more can be obtained in a range where the channel length L of the channel region CH in the semiconductor device 10 is 2 μm or more and 4 μm or less, and the channel width of the channel region CH is 2 μm or more and 25 μm or less. The mobility in the present embodiment is the field-effect mobility in a saturated region of the semiconductor device 10. Specifically, the mobility means the maximum value of the field-effect mobility in a region where the potential difference (Vd) between the source electrode and the drain electrode is greater than the value (Vg-Vth) obtained by subtracting the threshold voltage (Vth) of the semiconductor device 10 from the voltage (Vg) supplied to the gate electrode.

In the case of the top-gate transistor of the present embodiment, the interface between the metal oxide layer 130 and the oxide semiconductor layer 140 is the back-channel side of the transistor. By reducing the interface state density at the interface on the back-channel side, it is possible to suppress the electron from being trapped in the interface state. As a result, degradation of the transistor can be suppressed by the reliability test. That is, the reliability of the semiconductor device 10 can be improved.

### Third Embodiment

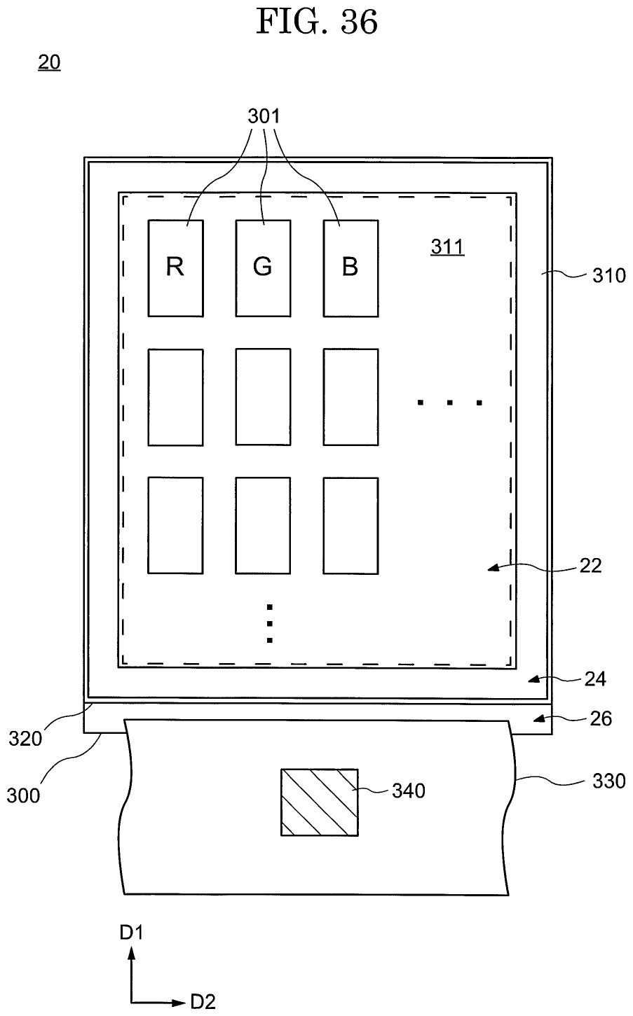

A display device using a semiconductor device according to an embodiment of the present invention will be described with reference to FIG. 36 to FIG. 40. In the embodiment described below, a configuration in which the semiconductor device 10 described in the first embodiment and the second embodiment is applied to a circuit of the liquid crystal display device will be described.

### [Outline of Display Device 20]

FIG. 36 is a plan view showing an outline of a display device according to an embodiment of the present invention. As shown in FIG. 36, a display device 20 includes an array substrate 300, a sealing part 310, a counter substrate 320, and a flexible printed circuit substrate 330 (FPC 330), and an IC chip 340. The array substrate 300 and the counter substrate 320 are bonded together by the sealing part 310. In the liquid crystal region 22 surrounded by the sealing part 310, a plurality of pixel circuits 301 is arranged in a matrix. The liquid crystal region 22 is a region that overlaps a liquid crystal element 311 described later in a plan view.

A sealing region 24 where the sealing part 310 is arranged is a region around the liquid crystal region 22. The FPC 330 is arranged in a terminal region 26. The terminal region 26 is a region where the array substrate 300 is exposed from the counter substrate 320 and is arranged outside the sealing region 24. The outside of the sealing region 24 means the outside of the region where the sealing part 310 is arranged and the region surrounded by the sealing part 310. The IC chip 340 is arranged on the FPC 330. The IC chip 340 supplies a signal for driving each pixel circuit 301.

### [Circuit Configuration of Display Device 20]

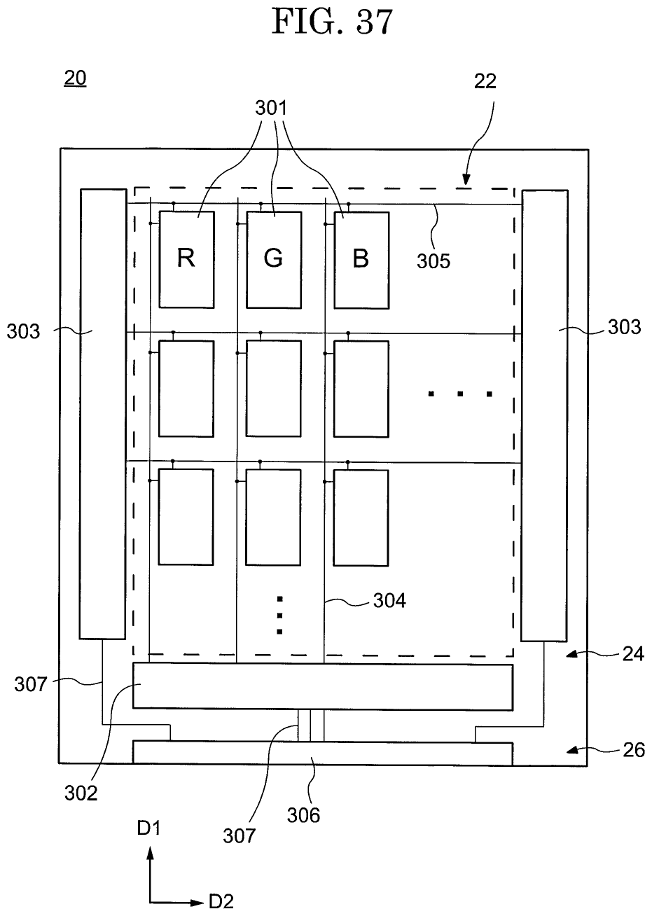

FIG. 37 is a block diagram showing a circuit configuration of the display device 20 according to an embodiment of the present invention. As shown in FIG. 37, a source driving circuit 302 is arranged at a position adjacent to the liquid crystal region 22 on which the pixel circuit 301 is arranged in the first direction D1 (column direction), and a gate driving circuit 303 is arranged at a position adjacent to the liquid crystal region 22 in the second direction D2 (row direction). The source driving circuit 302 and the gate driving circuit 303 are arranged in the sealing region 24. However, the region where the source driving circuit 302 and the gate driving circuit 303 are arranged is not limited to the sealing region 24, and any region may be used as long as it is outside the region where the pixel circuit 301 is arranged.

A source wiring 304 extends from the source driving circuit 302 in the first direction D1 and is connected to the plurality of pixel circuits 301 arranged in the first direction D1. A gate wiring 305 extends from the gate driving circuit 303 in the second direction D2 and is connected to the plurality of pixel circuits 301 arranged in the second direction D2.

A terminal part 306 is arranged in the terminal region 26. The terminal part 306 and the source driving circuit 302 are connected by a connecting wiring 307. Similarly, the terminal part 306 and the gate driving circuit 303 are connected by the connecting wiring 307. When the FPC 330 is connected to the terminal part 306, an external device to which the FPC 330 is connected is connected to the display device 20, and each pixel circuit 301 arranged in the display device 20 is driven by a signal from the external device.

The semiconductor device 10 according to the first embodiment and the second embodiment is used as the transistor included in the pixel circuit 301, the source driving circuit 302, and the gate driving circuit 303.

### [Pixel Circuit 301 of Display Device 20]

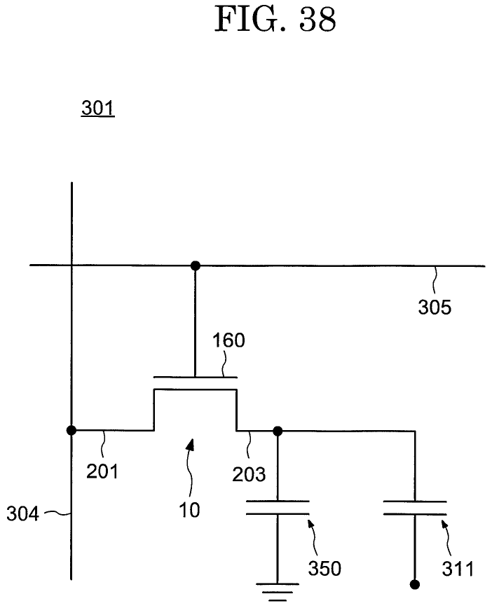

FIG. 38 is a circuit diagram showing a pixel circuit of the display device 20 according to an embodiment of the present invention. As shown in FIG. 38, the pixel circuit 301 includes elements such as the semiconductor device 10, a storage capacitor 350, and the liquid crystal element 311. The semiconductor device 10 includes the gate electrode 160, the source electrode 201, and the drain electrode 203. The gate electrode 160 is connected to the gate wiring 305. The source electrode 201 is connected to the source wiring 304. The drain electrode 203 is connected to the storage capacitor 350 and the liquid crystal element 311. In the present embodiment, for convenience of explanation, the electrode indicated by the reference sign “201” may be referred to as the source electrode, the electrode indicated by the reference sign “203” may be referred to as the drain electrode, but the electrode indicated by the reference sign “201” may function as the drain electrode, and the electrode indicated by the reference sign “203” may function as the source electrode.

### [Cross-Sectional Structure of Display Device 20]

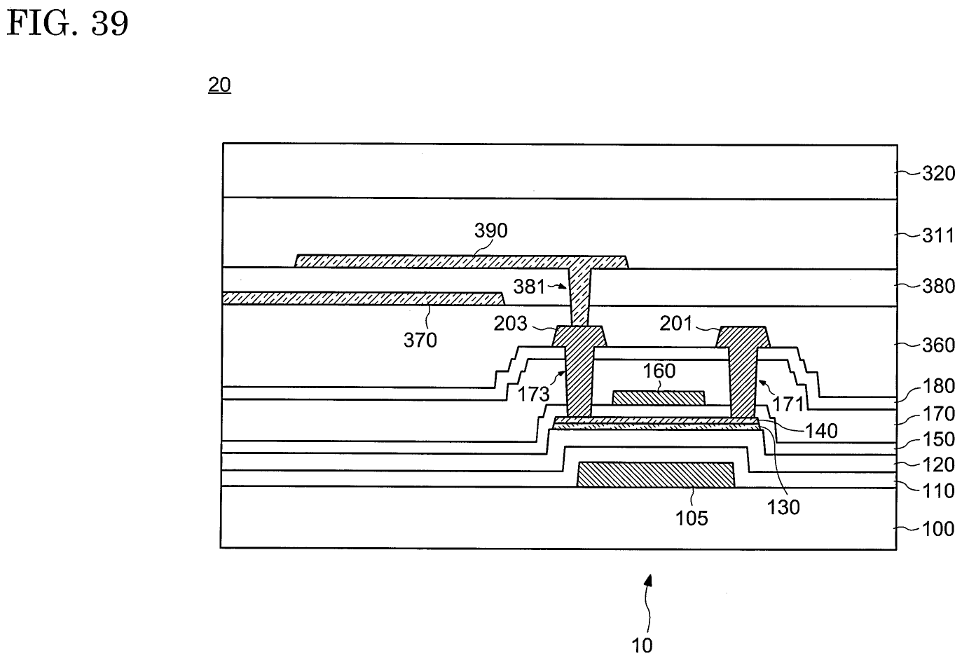

FIG. 39 is a cross-sectional view of a display device according to an embodiment of the present invention. As shown in FIG. 39, the display device 20 is a display device in which the semiconductor device 10 is used. Although a configuration in which the semiconductor device 10 is used for the pixel circuit 301 is exemplified in the present embodiment, the semiconductor device 10 may be used for a peripheral circuit including the source driving circuit 302 and the gate driving circuit 303. In the following description, since the configuration of the semiconductor device 10 is similar to that of the semiconductor device 10 shown in FIG. 1, the description thereof will be omitted.

An insulating layer 360 is arranged on the source electrode 201 and the drain electrode 203. A common electrode 370 arranged in common to the plurality of pixels is arranged on the insulating layer 360. An insulating layer 380 is arranged on the common electrode 370. An opening 381 is arranged in the insulating layers 360 and 380. A pixel electrode 390 is arranged on the insulating layer 380 and inside the opening 381. The pixel electrode 390 is connected to the drain electrode 203.

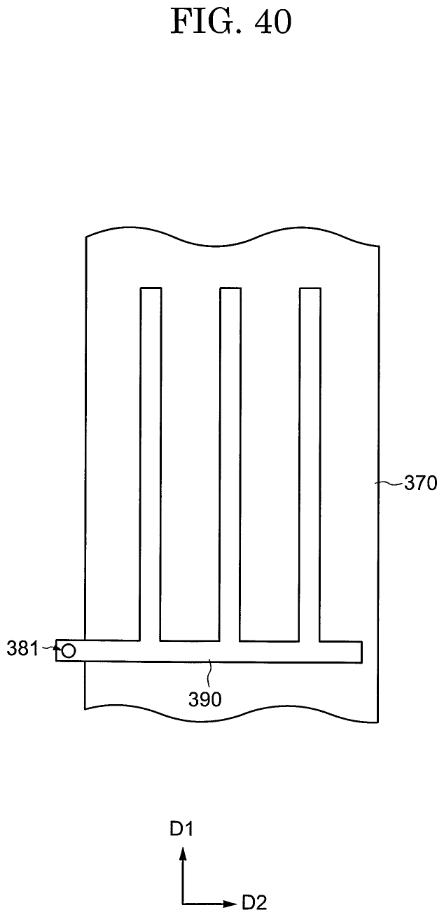

FIG. 40 is a plan view of a pixel electrode and a common electrode of a display device according to an embodiment of the present invention. As shown in FIG. 40, the common electrode 370 has an overlapping region that overlaps the pixel electrode 390 in a plan view and a non-overlapping region that does not overlap the pixel electrode 390. When a voltage is supplied between the pixel electrode 390 and the common electrode 370, a lateral electric field is formed from the pixel electrode 390 in the overlapping region toward the common electrode 370 in the non-overlapping region. When liquid crystal molecules contained in the liquid crystal element 311 are operated by the lateral electric field, the gradation of the pixel is determined.

The semiconductor device 10 according to an embodiment of the present invention may be configured such that the amount of variation in the threshold voltage due to aging is small. The display device using the semiconductor device 10 has high reliability and can have a long life.

### Fourth Embodiment

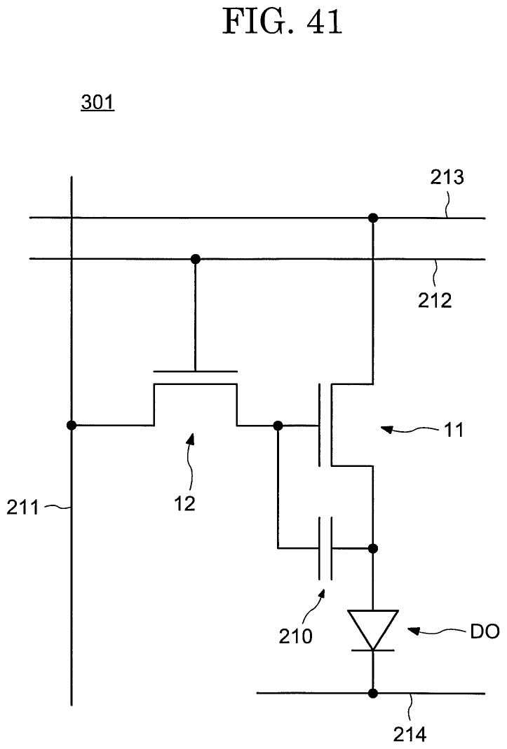

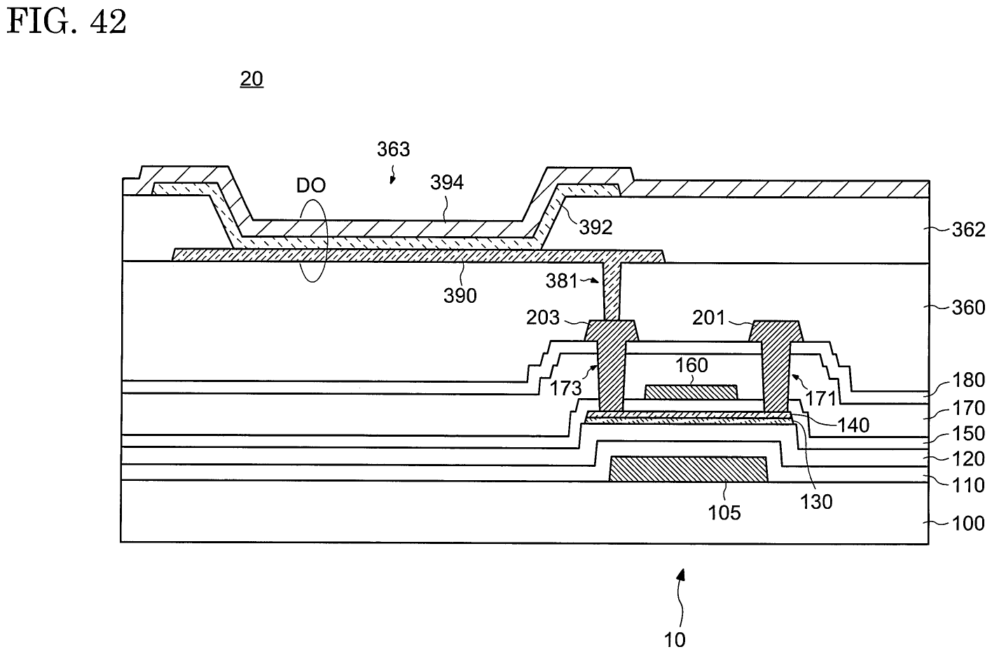

The display device 20 using the semiconductor device 10 according to an embodiment of the present invention will be described with reference to FIG. 41 and FIG. 42. In the present embodiment, a configuration in which the semiconductor device 10 described in the first embodiment and the second embodiment is applied to the circuit of the organic EL display device will be described. Since the outline and the circuit configuration of the display device 20 are similar to those shown in FIG. 36 and FIG. 37, the description thereof will be omitted.

### [Pixel Circuit 301 of Display Device 20]

FIG. 41 is a circuit diagram showing a pixel circuit of a display device according to an embodiment of the present invention. As shown in FIG. 41, the pixel circuit 301 includes elements such as a driving transistor 11, a selecting transistor 12, a storage capacitor 210, and a light-emitting element DO. The driving transistor 11 and the selecting transistor 12 have the same configuration as that of the semiconductor device 10. A source electrode of the selecting transistor 12 is connected to a signal line 211, and a gate electrode of the selecting transistor 12 is connected to a gate wiring 212. A source electrode of the driving transistor 11 is connected to an anode power source line 213, and a drain electrode of the driving transistor 11 is connected to one end of the light-emitting element DO. The other end of the light-emitting element DO is connected to a cathode power source line 214. A gate electrode of the driving transistor 11 is connected to the drain electrode of the selecting transistor 12. The storage capacitor 210 is connected to the gate electrode and the drain electrode of the driving transistor 11. A gradation signal that determines the emission intensity of the light-emitting element DO is supplied to the signal line 211. A signal for selecting a pixel row to which the gradation signal is written is supplied to the gate wiring 212.

### [Cross-Sectional Structure of Display Device 20]

FIG. 42 is cross-sectional view of the display device 20 according to an embodiment of the present invention. The configuration of the display device 20 shown in FIG. 42 is similar to that of the display device 20 shown in FIG. 39, but the structure above the insulating layer 360 of the display device 20 in FIG. 42 is different from the structure above the insulating layer 360 of the display device 20 in FIG. 39. Hereinafter, among the configurations of the display device 20 of FIG. 42, similar configurations as those of the display device 20 of FIG. 39 will be omitted, and differences between the two will be described.

As shown in FIG. 42, the display device 20 has the pixel electrode 390, a light-emitting layer 392, and a common electrode 394 (the light-emitting element DO) above the insulating layer 360. The pixel electrode 390 is arranged on the insulating layer 360 and inside the opening 381. An insulating layer 362 is arranged on the pixel electrode 390. An opening 363 is arranged in the insulating layer 362. The opening 363 corresponds to the light-emitting region. That is, the insulating layer 362 defines a pixel. The light-emitting layer 392 and the common electrode 394 are arranged on the pixel electrode 390 exposed by the opening 363. The pixel electrode 390 and the light-emitting layer 392 are arranged separately for each pixel. On the other hand, the common electrode 394 is arranged in common to the plurality of pixels. The light-emitting layer 392 is made of a material that differs depending on the color of the pixel.

The semiconductor device 10 according to an embodiment of the present invention may be configured such that the amount of variation in the threshold voltage due to aging is small. The display device 20 using the semiconductor device 10 has high reliability and can have a long life.

In the third embodiment and the fourth embodiment, although the configuration in which the semiconductor device 10 described in the first embodiment and the second embodiment is applied to the liquid crystal display device and the organic EL display device is exemplified, the semiconductor device 10 may be applied to a display device (for example, a self-luminous display device or an electronic paper display device other than the organic EL display device) other than the display devices. In addition, the semiconductor device 10 can be applied from a medium-sized display device to a large-sized display device without any particular limitation.

### EXAMPLES

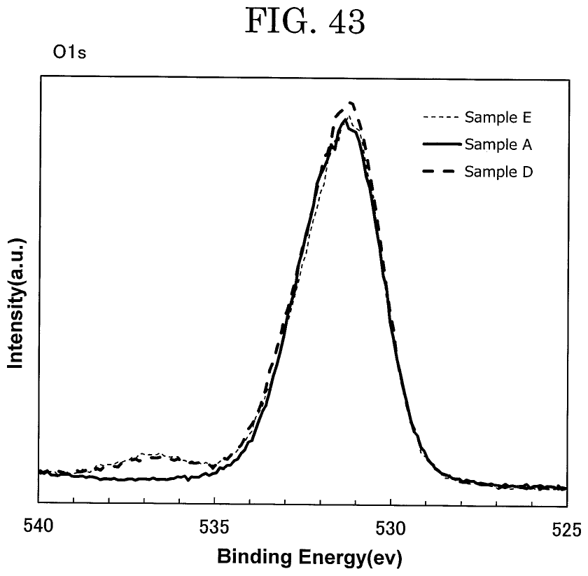

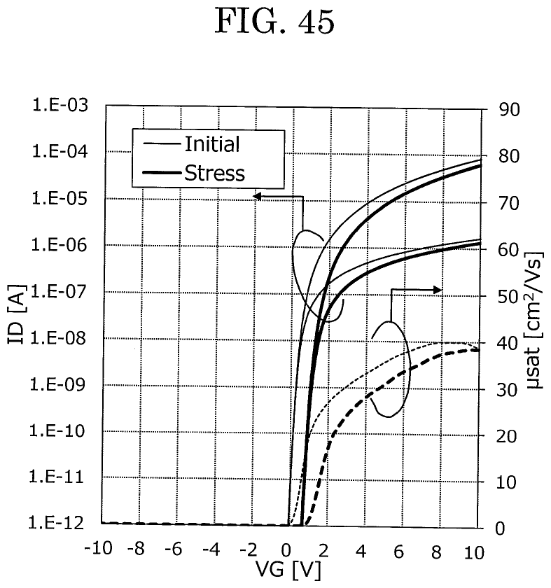

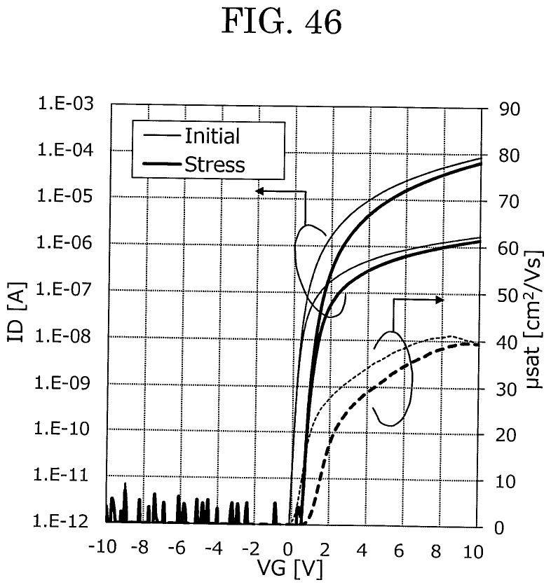

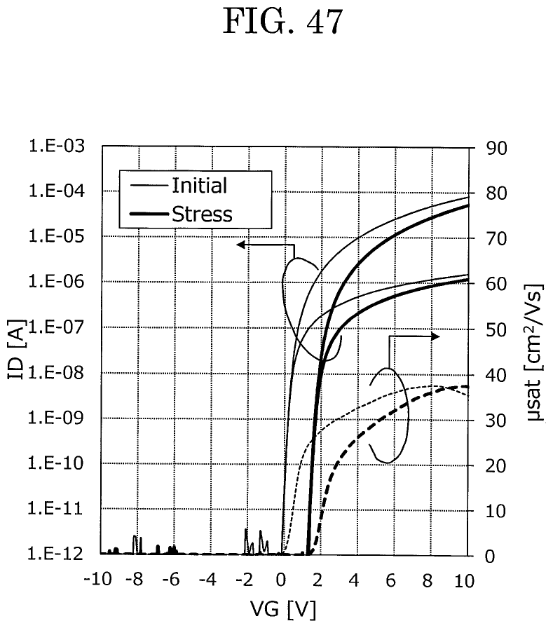

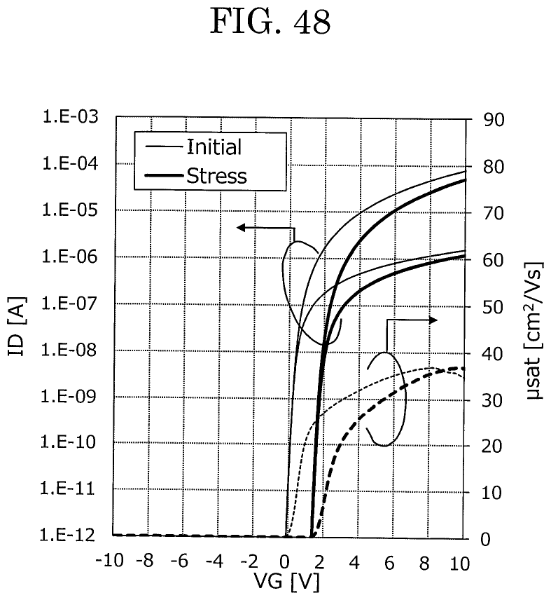

In the present example, the effect of the plasma treatment on the surface of the metal oxide layer containing aluminum as a main component will be described with reference to FIG. 43 to FIG. 48.

### [Relationship Between Water Contact Angle of Aluminum Oxide Layer and Electrical Characteristics of Semiconductor Device]

To investigate the water contact angle of aluminum oxide layer, Sample A to Sample E were prepared according to the following conditions.

First, an aluminum oxide layer was formed to a thickness of 11 nm on a glass substrate by the sputtering method.

### [Condition 1]

For sample A, the reverse sputtering process using argon gas was performed on the surface of the aluminum oxide layer using a sputtering device having a reverse sputtering function. The conditions of the reverse sputtering were an upper RF power source of 400 kHz (1.5 kV), a lower RF power source of 13.56 MHZ (1.5 kV), argon gas flow rate 5 sccm, a room temperature (25° C.), and a processing time 40 seconds. The thickness of the aluminum oxide layer after the reverse sputtering process became 10 nm.

### [Condition 2]

For Sample B, the etching process by the inductively coupled plasma using argon gas was performed on the surface of the oxide aluminum layer using an ICP etching device. The conditions of the etching process were ICP power 50 W (per unit electrode area (power density) 0.81 W/cm²), pressure 4 Pa, argon gas flow rate 50 sccm, RF bias power 50 W, a temperature 65° C., and a processing time 399.9 seconds. The thickness of the aluminum oxide layer after the etching process became 10 nm.

### [Condition 3]

For Sample C, the etching process by the inductively coupled plasma using argon gas was performed on the surface of the oxide aluminum layer using the ICP etching device. The conditions of the etching process were ICP power 25 W, pressure 4 Pa, argon gas flow rate 50 sccm, RF bias power 25 W, a temperature 65° C., and a processing time 1100 seconds. The thickness of the aluminum oxide layer after the etching process became 10 nm.

### [Condition 4]

For Sample D, the surface of the aluminum oxide layer was processed using a developer (TMAH) for 5 seconds.

### [Condition 5]

The sample E was not subjected to a surface modification treatment on the surface of the aluminum oxide layer.

Next, water contact angles at the outermost surfaces of the aluminum oxide layers of Samples A to E were measured. The water contact angle of the aluminum oxide layer was measured by the CA-S350 manufactured by Kyowa Interface Science Co., Ltd. In addition, pure water was dropped so as to have a diameter of 1.5 mm to 2.0 mm, and the water contact angle was measured within 10 seconds after the water contacted the surface of the aluminum oxide layer.

Table 1 shows the measurement results of the water contact angle on the outermost surface of the aluminum oxide layer of Samples A to E.

TABLE 1

| | Sample A | Sample B | Sample C | Sample D | Sample E |
|---|---|---|---|---|---|
| Water | 19.0 | 7.0 | 8.0 | 37.4 | 33.8 |
| contact | | | | | |
| angle (°) | | | | | |

As shown in Table 1, it was confirmed that the water contact angles of the samples A to C subjected to the plasma treatment on the aluminum oxide layer were smaller than the water contact angles of the samples D and E. In addition, it was confirmed that the water contact angles of Sample B and Sample C subjected to the etching process by the inductively coupled plasma were smaller than the water contact angle of Sample A subjected to the reverse sputtering.

### [Analysis by X-Ray Photoelectron Spectroscopy (XPS)]

Next, the film surfaces of the aluminum oxide layers were subjected to XPS analysis on the sample A, the sample D, and the sample E, and the proportions of Al atoms, O atoms, F atoms, C atoms, CI atoms, Si atoms, and Ar atoms present on the surfaces were measured. The results of the XPS analyses of Sample A, Sample D, and Sample E are shown in Table 2.

TABLE 2

| | XPS spectrometry (atomic %) | | | | | | |
|---|---|---|---|---|---|---|---|
| Sample name | Al | O | F | C | Cl | Si | Ar |
| Sample A | 29.1 | 56.6 | 1.0 | 9.4 | 2.3 | 0.2 | 1.3 |
| Sample D | 29.4 | 59.9 | 1.1 | 8.8 | 0.0 | 0.7 | 0.0 |
| Sample E | 30.7 | 59.0 | 0.8 | 9.4 | 0.0 | 0.0 | 0.0 |

FIG. 43 shows O1s peaks due to oxygen atoms on the surface of the aluminum oxide layer in Sample A, Sample D, and Sample E. As shown in Table 2 and FIG. 43, it was confirmed that the oxygen concentration (atomic %) contained on the surface of the aluminum oxide layer in Sample A was lower than the oxygen concentration (atomic %) contained on the surface of the aluminum oxide layer in Samples D and E. That is, it can be predicted that the hydroxyl groups and the water contained on the surface of the aluminum oxide layer in the sample A are less than the hydroxyl groups and the water contained on the surface of the aluminum oxide layer in the sample D and the sample E.

### [Reliability Test]

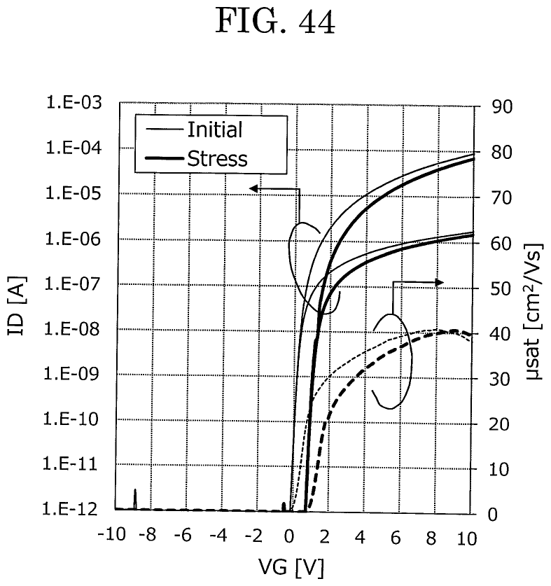

Next, semiconductor devices A to E are manufactured, and the reliability test results on each semiconductor device will be described with reference to FIG. 44 to FIG. 48.

Semiconductor devices A to E were manufactured according to the method for manufacturing semiconductor device 10 shown in FIG. 24 (see steps S2001 to S2016 in FIG. 24). In this case, when the semiconductor device A was manufactured, the aluminum oxide layer was subjected to the plasma treatment using Condition 1 in step S2003. In addition, when the semiconductor device B was manufactured, the aluminum oxide layer was subjected to the plasma treatment using Condition 2 in step S2003. In addition, when the semiconductor device C was manufactured, the aluminum oxide layer was subjected to the plasma treatment using Condition 3 in step S2003. In addition, when the semiconductor device D was manufactured, the aluminum oxide layer was subjected to the plasma treatment using Condition 4 in step S2003. When the semiconductor device E was manufactured, step S2003 was omitted (Condition 5). In the present embodiment, the oxide semiconductor layer 140 contains two or more metals including indium, and the proportion of indium in the two or more metals is 50% or more, which is a polycrystalline oxide semiconductor.

Subsequently, a PBTS reliability test was performed on the semiconductor devices A to E. Conditions for the PBTS reliability test are as follows.
The size of the channel region CH: W/L=2. μm/2.5 μm
Light irradiation conditions: No irradiation (dark room)
Gate voltage: +30 V
Source and drain voltage: 0 V
Stage temperature at the time of stress application: 85° C.
Time: 1000 seconds

FIG. 44 to FIG. 48 are diagrams showing reliability test results of the semiconductor device A to the semiconductor device E. In FIG. 44 to FIG. 48, the thin solid line represents a drain current of 0 seconds (Initial), and the thick solid line represents a drain current of 1000 seconds (Stress). In addition, the thin dotted line is the mobility of 0 seconds, and the thick dotted line is the mobility after 1000 seconds. Furthermore, Table 3 shows the amount of threshold voltage shift (ΔVth) and mobility (u) after 1000 seconds.

TABLE 3

| | Sample | Sample | Sample | Sample | Sample |
|---|---|---|---|---|---|
| | A | B | C | D | E |
| ΔVth(V) | 0.90 | 0.81 | 0.76 | 1.5 | 1.5 |
| μ(cm²/V · s) | 40 | 42 | 42 | 38 | 37 |

As shown in Table 3, it can be seen that, for the semiconductor devices A to C, the threshold voltages are shifted to positive by only 0.90 V, 0.81 V, 0.76 V, whereas for the semiconductor devices D and E using Sample D and Sample E, the threshold voltages are shifted to positive by 1.5 V. It was confirmed that the reliability of the semiconductor device was improved by performing the plasma treatment on the aluminum oxide layer. Furthermore, it was confirmed that the fluctuation in threshold can be suppressed more effectively in the semiconductor devices B and C, which were etched by the inductively coupled plasma than that of the semiconductor device A which was subjected to the plasma treatment using reverse sputtering.

In addition, as shown in Table 3, it can be seen that the mobility is 38 cm²/V/s and 37 cm²/V·s for the semiconductor devices D and E, whereas the mobility is 40 cm²/V/s, 42 cm²/V·s, and 42 cm²/V·s for the semiconductor devices A to C. It was confirmed that the mobility of the semiconductor device was improved by performing the plasma treatment on the aluminum oxide layer. In addition, it was confirmed that the mobility of the semiconductor devices B and C which were etched by the inductively coupled plasma was higher than that of the semiconductor device A which was subjected to the plasma treatment using reverse sputtering.

As a result, it was confirmed that the mobility and reliability of the semiconductor device were improved by performing the plasma treatment on the aluminum oxide layer. In addition, it was confirmed that the electrical characteristics of the semiconductor device were improved as the water contact angle of the aluminum oxide layer was decreased. That is, it is considered that the water and oxygen deficiencies in the oxide semiconductor layer are reduced at the interface between the aluminum oxide layer and the oxide semiconductor layer. In particular, it is considered that even when the oxide semiconductor layer having a relatively high proportion of indium is used, the formation of oxygen deficiencies at the interface is suppressed. Therefore, it is considered that the crystallinity of the oxide semiconductor layer arranged on the aluminum oxide layer is improved, and polycrystals with reduced defects are formed. As a result, it is considered that the mobility and reliability of the semiconductor device are improved.

Each of the embodiments described above as an embodiment of the present invention can be appropriately combined and implemented as long as no contradiction is caused. Furthermore, the addition, deletion, or design change of components, or the addition, deletion, or condition change of processes as appropriate by those skilled in the art based on the semiconductor device and display device of each embodiment are also included in the scope of the present invention as long as they are provided with the gist of the present invention.

It is understood that, even if the effect is different from those provided by each of the above-described embodiments, the effect obvious from the description in the specification or easily predicted by persons ordinarily skilled in the art is apparently derived from the present invention.

What is claimed is:

1. A semiconductor device comprising:
a metal oxide layer containing aluminum as a main component above an insulating surface;
an oxide semiconductor layer on the metal oxide layer;
a gate electrode facing the oxide semiconductor layer; and
a gate insulating layer between the oxide semiconductor layer and the gate electrode,
wherein
a water contact angle on an upper surface of the metal oxide layer is 20° or lower.

2. The semiconductor device according to claim 1, wherein
the water contact angle on the upper surface of the metal oxide layer is 15° or lower.

3. The semiconductor device according to claim 1, wherein
an upper portion of the metal oxide layer contains 1 atomic % or more and 3 atomic % or less.

4. The semiconductor device according to claim 1, wherein
a thickness of the metal oxide layer is 1 nm or more and 20 nm or less.

5. The semiconductor device according to claim 1, wherein
the metal oxide layer has barrier properties against oxygen and hydrogen.

6. The semiconductor device according to claim 1, wherein
the oxide semiconductor layer includes two or more metals, including indium, and a ratio of indium to the two or more metals is 50% or more.

7. The semiconductor device according to claim 1, wherein
the oxide semiconductor layer is a polycrystalline oxide semiconductor layer.

8. The semiconductor device according to claim 1, wherein
a field-effect mobility is 40 cm²/V·s or more.

9. A method for manufacturing semiconductor device comprising:
forming a metal oxide layer containing aluminum as a main component on an insulating surface;
plasma-treating a surface of the metal oxide layer so that a water contact angle on the insulating surface of the metal oxide layer is 20° or less;
forming an oxide semiconductor on the surface of the metal oxide layer that has been plasma-treated;
forming a gate insulating layer on the oxide semiconductor layer; and
forming a gate electrode facing the oxide semiconductor layer on the gate insulating layer.

10. The method according to claim 9, wherein
the plasma treatment is carried out using reverse sputtering with argon gas.

11. The method according to claim 9, wherein
the water contact angle on an upper surface of the metal oxide layer is 15° or less.

12. The method according to claim 9, wherein
the plasma treatment is carried out using inductively coupled plasma etching with argon gas.

13. The method according to claim 9, wherein
a thickness of the metal oxide layer after the plasma treatment is 1 nm or more and 20 nm or less.

14. The method according to claim 9, the method further comprising:
forming a metal oxide layer containing aluminum as a main component on the gate insulating layer after forming the gate insulating layer;
performing heat treatment with the metal oxide layer formed on the gate insulating layer; and
removing the metal oxide layer after the heat treatment.
